(19) United States
(12) Patent Application Publication
(10) Pub. No.: US 2013/0092923 A1
(43) Pub. Date: Apr. 18, 2013

(54) ACTIVE MATRIX SUBSTRATE AND METHOD FOR MANUFACTURING THE SAME

(71) Applicants: Takeshi Hara, Osaka-shi (JP); Hirohiko Nishiki, Osaka-shi (JP); Yoshifumi Ohta, Osaka-shi (JP); Yoshimasa Chikama, Osaka-shi (JP); Tetsuya Aita, Osaka-shi (JP); Masahiko Suzuki, Osaka-shi (JP); Michiko Takei, Osaka-shi (JP); Okifumi Nakagawa, Osaka-shi (JP); Yoshiyuki Harumoto, Osaka-shi (JP); Hinae Mizuno, Yamato-shi (JP)

(72) Inventors: Takeshi Hara, Osaka-shi (JP); Hirohiko Nishiki, Osaka-shi (JP); Yoshifumi Ohta, Osaka-shi (JP); Yuuji Mizuno, Osaka-shi (JP); Yoshimasa Chikama, Osaka-shi (JP); Tetsuya Aita, Osaka-shi (JP); Masahiko Suzuki, Osaka-shi (JP); Michiko Takei, Osaka-shi (JP); Okifumi Nakagawa, Osaka-shi (JP); Yoshiyuki Harumoto, Osaka-shi (JP)

(73) Assignee: SHARP KABUSHIKI KAISHA, Osaka-shi, Osaka (JP)

(21) Appl. No.: 13/521,316

(22) PCT Filed: Jan. 12, 2011
(86) PCT No.: PCT/JP2011/000104

§ 371 Date: Sep. 21, 2012

(30) Foreign Application Priority Data
Jan. 13, 2010 (JP) 2010-005199

(51) Int. Cl. H01L 29/786; H01L 29/66

(52) U.S. Cl. CPC H01L 29/786; H01L 29/66742
USPC 257/43; 438/34

(57) ABSTRACT

An active matrix substrate includes a plurality of pixel electrodes (19a) arranged in a matrix, and a plurality of TFTs (5a) connected to the respective corresponding pixel electrodes (19a). Each TFT (5a) includes a gate electrode (11aa) provided on an insulating substrate (10a), a gate insulating layer (12) covering the gate electrode (11aa), an oxide semiconductor layer (13a) provided on the gate insulating layer (12) over the gate electrode (11aa) and having a channel region (C), and a source electrode (16aa) and a drain electrode (16b) provided on the oxide semiconductor layer (13a), overlapping the gate electrode (11aa) and facing each other with the channel region (C) being interposed between the source and drain electrodes. A protection insulating layer (17) made of a spin-on glass material is provided on the channel region (C) of the oxide semiconductor layer (13a).

### TECHNICAL FIELD

The present invention relates to active matrix substrates and methods for manufacturing the active matrix substrates, and more particularly, to an active matrix substrate including a semiconductor layer made of an oxide semiconductor and a method for manufacturing the active matrix substrate.

### BACKGROUND ART

In recent years, a thin film transistor (hereinafter also referred to as a “TFT”) including a semiconductor layer made of an oxide semiconductor (hereinafter also referred to as an “oxide semiconductor layer”) has been proposed, which is used as a switching element in each pixel, which is the smallest unit of an image, in an active matrix substrate, instead of a conventional thin film transistor including a semiconductor layer made of amorphous silicon.

For example, PATENT DOCUMENT 1 describes an active matrix-type image display device in which the active layer of a field effect transistor for driving a light control element is made of an amorphous oxide which has a predetermined electron carrier concentration.

PATENT DOCUMENT 2 describes a TFT including an In—M—Zn—O (M is at least one of Ga, Al, and Fe) thin film (e.g., a transparent oxide thin film, etc.) as a channel layer, in which the oxide semiconductor channel layer is covered with a protection film, whereby unstable operation due to a change in ambient atmosphere is prevented, and therefore, stable TFT operating characteristics are obtained.

PATENT DOCUMENT 3 describes a method for manufacturing an oxide semiconductor TFT in which a surface of the oxide semiconductor channel layer is oxidized with an oxidant to adjust the carrier density of the channel layer surface.

### CITATION LIST

### Patent Documents

PATENT DOCUMENT 1: Japanese Patent Publication No. 2006-165528

PATENT DOCUMENT 2: Japanese Patent Publication No. 2007-73705

PATENT DOCUMENT 3: United States Patent Publication No. 2009/140243

### SUMMARY OF THE INVENTION

### Technical Problem

FIG. 17 is a cross-sectional view of a conventional active matrix substrate 120 including a TFT 105 employing an oxide semiconductor layer.

As shown in FIG. 17, the active matrix substrate 120 includes an insulating substrate 110, the TFT 105 provided on the insulating substrate 110, a protection insulating layer 115 covering the TFT 105, an interlayer insulating layer 116 covering the protection insulating layer 115, and a pixel electrode 117 provided on the interlayer insulating layer 116 and connected to the TFT 105. Here, as shown in FIG. 17 the TFT 105 includes a gate electrode 111 provided on the insulating substrate 110, a gate insulating layer 112 covering the gate electrode 111, an island-like oxide semiconductor layer 113 provided on the gate insulating layer 112 over the gate electrode 111, and a source electrode 114a and a drain electrode 114b provided on the oxide semiconductor layer 113, overlapping the gate electrode 111 and facing each other.

Incidentally, the protection insulating layer 115 is often formed, for example, by forming an inorganic insulating film by plasma-enhanced chemical vapor deposition (CVD) and patterning the inorganic insulating film. Therefore, in the case of the active matrix substrate 120, a channel region C of the oxide semiconductor layer 113 exposed through the source electrode 114a and the drain electrode 114b is likely to be damaged by plasma, resulting in a degradation in characteristics of the TFT 105. In order to reduce the degradation in TFT characteristics, attempts have been made, such as modification of the method of forming the inorganic insulating film by plasma-enhanced CVD, introduction of a surface treatment or an annealing treatment for the oxide semiconductor layer, etc. However, the effects of these attempts are insufficient or additional manufacturing steps are required. Therefore, there is room for improvement.

The present invention has been made in view of the above problems. It is an object of the present invention to reduce an increase in the number of manufacturing steps, reduce damage to the oxide semiconductor layer, and obtain more satisfactory TFT characteristics.

### Solution To The Problem

To achieve the object, in the present invention, a protection insulating layer made of a spin-on glass material is provided on the channel region of the oxide semiconductor layer.

An active matrix substrate includes a plurality of pixel electrodes arranged in a matrix, and a plurality of thin film transistors connected to the respective corresponding pixel electrodes. Each of the thin film transistors includes a gate electrode provided on an insulating substrate, a gate insulating layer covering the gate electrode, an oxide semiconductor layer provided on the gate insulating layer and having a channel region over the gate electrode, and a source electrode and a drain electrode provided on the oxide semiconductor layer, overlapping the gate electrode and facing each other with the channel region being interposed between the source and drain electrodes. A protection insulating layer made of a spin-on glass material is provided on the channel region of the oxide semiconductor layer.

With this configuration, the protection insulating layer made of a spin-on glass material is provided on the channel region of the oxide semiconductor layer. Specifically, a spin-on glass material is applied on the oxide semiconductor layer by spin coating or slit coating, and baking and patterning are performed on the applied film, to form the protection insulating layer. Therefore, the channel region of the oxide semiconductor layer is not exposed to plasma, and therefore, the damage to the channel region of the oxide semiconductor layer is reduced. When the protection insulating layer is formed, the applied film of the spin-on glass material is baked. During the baking, H₂O occurs due to dehydration polymerization reaction of the spin-on glass material. Here, when patterning is performed on the metal film by dry etching in order to form the source and drain electrodes, a surface layer of the channel region of the oxide semiconductor layer is also etched, i.e., the channel region of the oxide semiconductor layer is damaged. However, when the applied film is baked, H₂O occurs, and therefore, the oxide semiconductor layer is annealed in the presence of H₂O, and therefore, the damage to the channel region of the oxide semiconductor layer is satisfactorily repaired. Thus, by forming the protection insulating layer by applying, baking, and patterning the spin-on glass material, the damage to the channel region of the oxide semiconductor layer is reduced and repaired. As a result, an increase in the number of manufacturing steps can be reduced, the damage to the oxide semiconductor layer can be reduced, and satisfactory TFT characteristics can be obtained.

In contrast to this, if the protection insulating layer is formed of a plasma-enhanced chemically deposited film (CVD film), the channel region of the oxide semiconductor layer is damaged by plasma, and when the damaged oxide semiconductor layer is repaired by an annealing treatment, a sufficient amount of O₂ is not likely to be supplied to the oxide semiconductor layer due the CVD film provided on a surface of the oxide semiconductor layer, and therefore, the oxide semiconductor layer is not likely to be sufficiently repaired. If the hydrogen concentration of the CVD film increases, O₂ is conversely extracted as H₂O from the oxide semiconductor layer. Note that there has been a finding obtained by thermal desorption spectroscopy (TDS) on the CVD film and the film made of a spin-on glass (SOG) material that, in the CVD film, H₂O does not occur even if the temperature increases to about 450° C., while, in the SOG film, H₂O begins to occur at about 150° C. due to dehydration polymerization reaction of the spin-on glass material before the temperature reaches about 450° C.

The protection insulating layer may be provided to cover the source and drain electrodes.

With this configuration, the protection insulating layer is provided to cover the source and drain electrodes. Therefore, the thin film transistor is implemented so that the source and drain electrodes are covered by the protection insulating layer provided on the channel region of the oxide semiconductor layer.

Each pixel electrode may be provided on the protection insulating layer. With this configuration, each pixel electrode is provided on the protection insulating layer. Therefore, the insulating layer provided between each pixel electrode and the corresponding thin film transistor has a single-layer structure including the protection insulating layer. As a result, the manufacturing cost of the active matrix substrate is reduced.

An interlayer insulating layer may be provided on the protection insulating layer, and each pixel electrode may be provided on the interlayer insulating layer. With this configuration, an interlayer insulating layer is provided on the protection insulating layer, and each pixel electrode is provided on the interlayer insulating layer. Therefore, the insulating layer between each pixel electrode and the corresponding thin film transistor has a multilayer structure including the protection insulating layer and the interlayer insulating layer.

The protection insulating layer may be provided between the source and drain electrodes and the oxide semiconductor layer.

With this configuration, the protection insulating layer is provided between the source and drain electrodes and the oxide semiconductor layer. The thin film transistor is implemented as an etch stopper-type thin film transistor in which the protection insulating layer functions as a mask (etch stopper) for etching which is performed when the source and drain electrodes are formed. Therefore, a surface layer of the oxide semiconductor layer is less damaged during etching which is performed when the source and drain electrodes are formed, resulting in an improvement in TFT characteristics.

An interlayer insulating layer may be provided over the source and drain electrodes, covering the protection insulating layer.

With this configuration, an interlayer insulating layer is provided over the source and drain electrodes, covering the protection insulating layer. Therefore, the thin film transistor is implemented as an etch stopper-type thin film transistor in which the protection insulating layer covered by the interlayer insulating layer functions as an etch stopper.

The interlayer insulating layer may be formed of a photosensitive resin film.

With this configuration, the interlayer insulating layer is formed of a photosensitive resin film. Therefore, the interlayer insulating layer having a single-layer structure can be formed without using a photoresist, resulting in a reduction in the manufacturing cost of the active matrix substrate.

The interlayer insulating layer may be formed of a multilayer film in which a chemically deposited film and a photosensitive resin film are successively stacked.

With this configuration, the interlayer insulating layer is formed of a multilayer film in which a chemically deposited film and a photosensitive resin film are successively stacked. Therefore, the interlayer insulating layer having a multilayer structure can be formed without using a photoresist, resulting in a reduction in the manufacturing cost of the active matrix substrate.

A method for manufacturing an active matrix substrate according to the present invention is provided. The active matrix substrate includes a plurality of pixel electrodes arranged in a matrix, and a plurality of thin film transistors connected to the respective corresponding pixel electrodes. Each of the thin film transistors includes a gate electrode provided on an insulating substrate, a gate insulating layer covering the gate electrode, an oxide semiconductor layer provided on the gate insulating layer and having a channel region over the gate electrode, and a source electrode and a drain electrode provided on the oxide semiconductor layer, overlapping the gate electrode and facing each other with the channel region being interposed between the source and drain electrodes. The method includes a gate electrode forming step of forming the gate electrode on the insulating substrate, a semiconductor layer forming step of forming the gate insulating layer to cover the gate electrode formed in the gate electrode forming step, and thereafter, forming the oxide semiconductor layer on the gate insulating layer, a source/drain forming step of forming the source and drain electrodes on the oxide semiconductor layer formed in the semiconductor layer forming step, and a protection insulating layer forming step of applying a spin-on glass material to cover the source and drain electrodes formed in the source/drain forming step, and thereafter, baking the applied spin-on glass material and patterning the baked spin-on glass material, to form a protection insulating layer on the channel region of the oxide semiconductor layer.

With this method, after the oxide semiconductor layer is formed in the semiconductor layer forming step, the source and drain electrodes are formed in the source/drain forming step. Therefore, the active matrix substrate including the thin film transistor in which the relatively small oxide semiconductor layer is formed separately from the formation of the source and drain electrodes, is manufactured. In the protection insulating layer forming step, a spin-on glass material is applied by spin coating or slit coating to cover the source and drain electrodes formed on the oxide semiconductor layer, and baking and patterning are performed on the applied film, to form the protection insulating layer on the channel region of the oxide semiconductor layer. Therefore, the channel region of the oxide semiconductor layer is not exposed to plasma, and therefore, the damage to the channel region of the oxide semiconductor layer is reduced. When the protection insulating layer is formed in the protection insulating layer forming step, the applied film of the spin-on glass material is baked. During the baking, H₂O occurs due to dehydration polymerization reaction of the spin-on glass material. Here, when patterning is performed on the metal film by dry etching in order to form the source and drain electrodes in the source/drain forming step, a surface layer of the channel region of the oxide semiconductor layer is also etched, i.e., the channel region of the oxide semiconductor layer is damaged. However, when the applied film is baked in the protection insulating layer forming step, H₂O occurs, and therefore, the oxide semiconductor layer is annealed in the presence of H₂O, and therefore, the damage to the channel region of the oxide semiconductor layer is satisfactorily repaired. Thus, by forming the protection insulating layer by applying, baking, and patterning the spin-on glass material, the damage to the channel region of the oxide semiconductor layer is reduced and repaired. As a result, an increase in the number of manufacturing steps can be reduced, the damage to the oxide semiconductor layer can be reduced, and satisfactory TFT characteristics can be obtained.

Another method for manufacturing an active matrix substrate according to the present invention is provided. The active matrix substrate includes a plurality of pixel electrodes arranged in a matrix, and a plurality of thin film transistors connected to the respective corresponding pixel electrodes. Each of the thin film transistors includes a gate electrode provided on an insulating substrate, a gate insulating layer covering the gate electrode, an oxide semiconductor layer provided on the gate insulating layer and having a channel region over the gate electrode, and a source electrode and a drain electrode provided on the oxide semiconductor layer, overlapping the gate electrode and facing each other with the channel region being interposed between the source and drain electrodes. The method includes a gate electrode forming step of forming the gate electrode on the insulating substrate, a semiconductor layer forming step of forming the gate insulating layer to cover the gate electrode formed in the gate electrode forming step, and thereafter, successively forming an oxide semiconductor film and a metal film on the gate insulating layer and patterning the metal film to form the source and drain electrodes, and patterning the oxide semiconductor film to form the oxide semiconductor layer, and a protection insulating layer forming step of applying a spin-on glass material to cover the source and drain electrodes formed in the semiconductor layer forming step, and thereafter, baking the applied spin-on glass material and patterning the baked spin-on glass material, to form a protection insulating layer on the channel region of the oxide semiconductor layer.

With this method, after the oxide semiconductor film and the metal film are successively formed in the semiconductor layer forming step, patterning is performed on the oxide semiconductor film which is located below the metal film to form the oxide semiconductor layer, and patterning is performed on the metal film which is located above the oxide semiconductor film to form the source and drain electrodes. Therefore, the active matrix substrate which includes the thin film transistor in which the relatively large oxide semiconductor layer is formed in conjunction with the formation of the source and drain electrodes, can be manufactured. In the protection insulating layer forming step, a spin-on glass material is applied on the oxide semiconductor layer by spin coating or slit coating to cover the source and drain electrodes, and baking and patterning are performed on the applied film, to form the protection insulating layer on the channel region of the oxide semiconductor layer. Therefore, the channel region of the oxide semiconductor layer is not exposed to plasma, and therefore, the damage to the channel region of the oxide semiconductor layer is reduced. When the protection insulating layer is formed in the protection insulating layer forming step, the applied film of the spin-on glass material is baked. During the baking, H₂O occurs due to dehydration polymerization reaction of the spin-on glass material. Here, when patterning is performed on the metal film by dry etching in order to form the source and drain electrodes in the source/drain forming step, a surface layer of the channel region of the oxide semiconductor layer is also etched, i.e., the channel region of the oxide semiconductor layer is damaged. However, when the applied film is baked in the protection insulating layer forming step, H₂O occurs, and therefore, the oxide semiconductor layer is annealed in the presence of H₂O, and therefore, the damage to the channel region of the oxide semiconductor layer is satisfactorily repaired. Thus, by forming the protection insulating layer by applying, baking, and patterning the spin-on glass material, the damage to the channel region of the oxide semiconductor layer is reduced and repaired. As a result, an increase in the number of manufacturing steps can be reduced, the damage to the oxide semiconductor layer can be reduced, and satisfactory TFT characteristics can be obtained.

In the semiconductor layer forming step, a photosensitive resin film may be formed on the metal film, and thereafter, half exposure may be performed on the photosensitive resin film, to form a resist pattern having a relatively thin portion in which the channel region is to be formed and a relatively thick portion in which the source and drain electrodes are to be formed, and thereafter, the metal film exposed through the resist pattern and the oxide semiconductor film which is located below the metal film may be etched to form the oxide semiconductor layer, and thereafter, the metal film exposed by removing a relatively thin portion of the resist pattern by reducing a thickness of the resist pattern may be etched to form the source and drain electrodes.

With this method, in the semiconductor layer forming step, a single halftone or graytone photomask having transparent, opaque, and translucent portions which allows half exposure is used to form, on the metal film, a resist pattern having a relatively thin portion in which the channel region of the oxide semiconductor layer is to be formed and a relatively thick portion in which the source and drain electrodes are to be formed. The resist pattern is used to form the oxide semiconductor layer, and a resist pattern obtained by decreasing a thickness of that resist pattern is used to form the source and drain electrodes. As a result, the manufacturing cost of the active matrix substrate is reduced.

In the semiconductor layer forming step, after patterning is performed on the metal film to form the source and drain electrodes, the oxide semiconductor film exposed through the source and drain electrodes may be etched to form the oxide semiconductor layer.

With this method, in the semiconductor layer forming step, after patterning is performed on the metal film to form the source and drain electrodes, the oxide semiconductor film exposed through the source and drain electrodes is etched to form the oxide semiconductor layer. Therefore, the thin film transistor is implemented so that a relatively large oxide semiconductor layer is formed in conjunction with the formation of the source and drain electrodes.

In the semiconductor layer forming step, a resist pattern may be formed on the metal film to cover portions in which the source and drain electrodes are to be formed, and thereafter, the metal film exposed through the resist pattern may be etched to form the source and drain electrodes, and reflowing may be performed on the resist pattern to cover a portion in which the channel region is to be formed, and thereafter, the oxide semiconductor film may be etched to form the oxide semiconductor layer.

With this method, in the semiconductor layer forming step, a resist pattern covering portions in which the source and drain electrodes are to be formed is formed on the metal film using a single photomask, the source and drain electrodes are formed using the resist pattern, and the oxide semiconductor layer is formed using a resist pattern obtained by reflowing that resist pattern. As a result, the manufacturing cost of the active matrix substrate is reduced.

Another method for manufacturing an active matrix substrate according to the present invention is provided. The active matrix substrate includes a plurality of pixel electrodes arranged in a matrix, and a plurality of thin film transistors connected to the respective corresponding pixel electrodes. Each of the thin film transistors includes a gate electrode provided on an insulating substrate, a gate insulating layer covering the gate electrode, an oxide semiconductor layer provided on the gate insulating layer and having a channel region over the gate electrode, and a source electrode and a drain electrode provided on the oxide semiconductor layer, overlapping the gate electrode and facing each other with the channel region being interposed between the source and drain electrodes. The method includes a gate electrode forming step of forming the gate electrode on the insulating substrate, a semiconductor layer forming step of forming the gate insulating layer to cover the gate electrode formed in the gate electrode forming step, and thereafter, forming the oxide semiconductor layer on the gate insulating layer, a protection insulating layer forming step of applying a spin-on glass material to cover the oxide semiconductor layer formed in the semiconductor layer forming step, and thereafter, baking the applied spin-on glass material and patterning the baked spin-on glass material, to form a protection insulating layer on the channel region of the oxide semiconductor layer, and a source/drain forming step of forming the source and drain electrodes on the protection insulating layer formed in the protection insulating layer forming step.

With this method, the oxide semiconductor layer is formed in the semiconductor layer forming step, and thereafter, the protection insulating layer forming step is performed before the source and drain electrodes are formed in the source/drain forming step. Therefore, the active matrix substrate including the thin film transistor in which a relatively small oxide semiconductor layer is formed separately from the formation of the source and drain electrodes, is manufactured. In the protection insulating layer forming step, a spin-on material is applied by spin coating or slit coating to cover the oxide semiconductor layer, and baking and patterning are performed on the applied film, to form the protection insulating layer on the channel region of the oxide semiconductor layer. Therefore, the channel region of the oxide semiconductor layer is not exposed to plasma, and therefore, the damage to the channel region of the oxide semiconductor layer is reduced. Also, when patterning is performed on the metal film by dry etching in order to form the source and drain electrodes in the source/drain forming step, the protection insulating layer on the channel region of the oxide semiconductor layer functions as an etch stopper for the oxide semiconductor layer, and therefore, the damage to the channel region of the oxide semiconductor layer is reduced. Also, when the protection insulating layer is formed in the protection insulating layer forming step, the applied film of the spin-on glass material is baked. During the baking, H₂O occurs due to dehydration polymerization reaction of the spin-on glass material. Therefore, when the applied film is baked in the protection insulating layer forming step, H₂O occurs, and therefore, the oxide semiconductor layer is annealed in the presence of H₂O. Therefore, even if the channel region of the oxide semiconductor layer is damaged, the damage to the channel region of the oxide semiconductor layer is satisfactorily repaired. Thus, by forming the protection insulating layer by applying, baking, and patterning the spin-on glass material, the damage to the channel region of the oxide semiconductor layer is reduced and repaired. As a result, an increase in the number of manufacturing steps can be reduced, the damage to the oxide semiconductor layer can be reduced, and satisfactory TFT characteristics can be obtained.

Another method for manufacturing an active matrix substrate according to the present invention is provided. The active matrix substrate includes a plurality of pixel electrodes arranged in a matrix, and a plurality of thin film transistors connected to the respective corresponding pixel electrodes. Each of the thin film transistors includes a gate electrode provided on an insulating substrate, a gate insulating layer covering the gate electrode, an oxide semiconductor layer provided on the gate insulating layer and having a channel region over the gate electrode, and a source electrode and a drain electrode provided on the oxide semiconductor layer, overlapping the gate electrode and facing each other with the channel region being interposed between the source and drain electrodes. The method includes a gate electrode forming step of forming the gate electrode on the insulating substrate, a protection insulating layer forming step of forming the gate insulating layer to cover the gate electrode formed in the gate electrode forming step, and thereafter, forming an oxide semiconductor film on the gate insulating layer, and thereafter, applying a spin-on glass material, and thereafter, baking the applied spin-on glass material and patterning the baked spin-on glass material, to form a protection insulating layer on a region in which the channel region of the oxide semiconductor layer is to be formed, and a semiconductor layer forming step of forming a metal film to cover the protection insulating layer formed in the protection insulating layer forming step, and thereafter, patterning the metal film, to form the source and drain electrodes, and thereafter, etching the oxide semiconductor film exposed through the source and drain electrodes to form the oxide semiconductor layer.

With this method, after the source and drain electrodes are formed in the semiconductor layer forming step, the oxide semiconductor layer is formed by utilizing the formation of the source and drain electrodes. Therefore, the active matrix substrate which includes the thin film transistor in which a relatively large oxide semiconductor layer is formed in conjunction with the formation of the source and drain electrodes, is manufactured.

In the protection insulating layer forming step, a spin-on material is applied by spin coating or slit coating to cover the oxide semiconductor film of which the oxide semiconductor layer is to be formed, and baking and patterning are performed on the applied film, to form the protection insulating layer on a region where the channel region of the oxide semiconductor layer is to be formed. Therefore, the channel region of the oxide semiconductor layer is not exposed to plasma, and therefore, the damage to the channel region of the oxide semiconductor layer is reduced. Also, when patterning is performed on the metal film by dry etching in order to form the source and drain electrodes in the semiconductor layer forming step, the protection insulating layer on the oxide semiconductor film functions as an etch stopper for the oxide semiconductor film, and therefore, the damage to the channel region of the oxide semiconductor layer is reduced. Also, when the protection insulating layer is formed in the protection insulating layer forming step, the applied film of the spin-on glass material is baked. During the baking, H₂O occurs due to dehydration polymerization reaction of the spin-on glass material. Therefore, when the applied film is baked in the protection insulating layer forming step, H₂O occurs, and therefore, the oxide semiconductor film of which the oxide semiconductor layer is to be formed is annealed in the presence of H₂O. Therefore, even if the region where the channel region of the oxide semiconductor layer is to be formed is damaged, the damage to the region where the channel region of the oxide semiconductor layer is to be formed is satisfactorily repaired. Thus, by forming the protection insulating layer by applying, baking, and patterning the spin-on glass material, the damage to the channel region of the oxide semiconductor layer is reduced and repaired. As a result, an increase in the number of manufacturing steps can be reduced, the damage to the oxide semiconductor layer can be reduced, and satisfactory TFT characteristics can be obtained.

### ADVANTAGES OF THE INVENTION

According to the present invention, the protection insulating layer made of a spin-on glass material is provided on the channel region of the oxide semiconductor layer. As a result, an increase in the number of manufacturing steps can be reduced, the damage to the oxide semiconductor layer can be reduced, and satisfactory TFT characteristics can be obtained.

### BRIEF DESCRIPTION OF THE DRAWINGS

FIG. 1 shows a cross-sectional view of a liquid crystal display panel including an active matrix substrate according to a first embodiment.

FIG. 2 shows a plan view of the active matrix substrate of the first embodiment.

FIG. 3 shows an enlarged plan view of the active matrix substrate of FIG. 2.

FIG. 4 shows a cross-sectional view of the active matrix substrate taken along line IV-IV of FIG. 3.

FIG. 5 shows a flowchart of a process of manufacturing the active matrix substrate of the first embodiment.

FIG. 6 shows cross-sectional views for describing the process of manufacturing the active matrix substrate of the first embodiment.

FIG. 7 shows cross-sectional views for describing a process of manufacturing a counter substrate facing the active matrix substrate of the first embodiment.

FIG. 8 shows cross-sectional views for describing a process of manufacturing an active matrix substrate according to a second embodiment.

FIG. 9 shows cross-sectional views for describing a process of manufacturing an active matrix substrate according to a third embodiment.

FIG. 10 shows cross-sectional views for describing a process of manufacturing an active matrix substrate according to a fourth embodiment.

FIG. 11 shows cross-sectional views for describing a process of manufacturing an active matrix substrate according to a fifth embodiment.

FIG. 12 shows cross-sectional views for describing a process of manufacturing an active matrix substrate according to a sixth embodiment.

FIG. 13 shows cross-sectional views for describing a process of manufacturing an active matrix substrate according to a seventh embodiment.

FIG. 14 shows cross-sectional views for describing a process of manufacturing an active matrix substrate according to an eighth embodiment.

FIG. 15 shows cross-sectional views for describing a process of manufacturing an active matrix substrate according to a ninth embodiment.

FIG. 16 shows cross-sectional views for describing a process of manufacturing an active matrix substrate according to a tenth embodiment.

FIG. 17 shows a cross-sectional view of a conventional active matrix substrate including a TFT including an oxide semiconductor layer.

### DESCRIPTION OF EMBODIMENTS

Embodiments of the present invention will be described in detail hereinafter with reference to the accompanying drawings. Note that the present invention is not intended to be limited to the embodiment described below.

### First Embodiment of the Invention

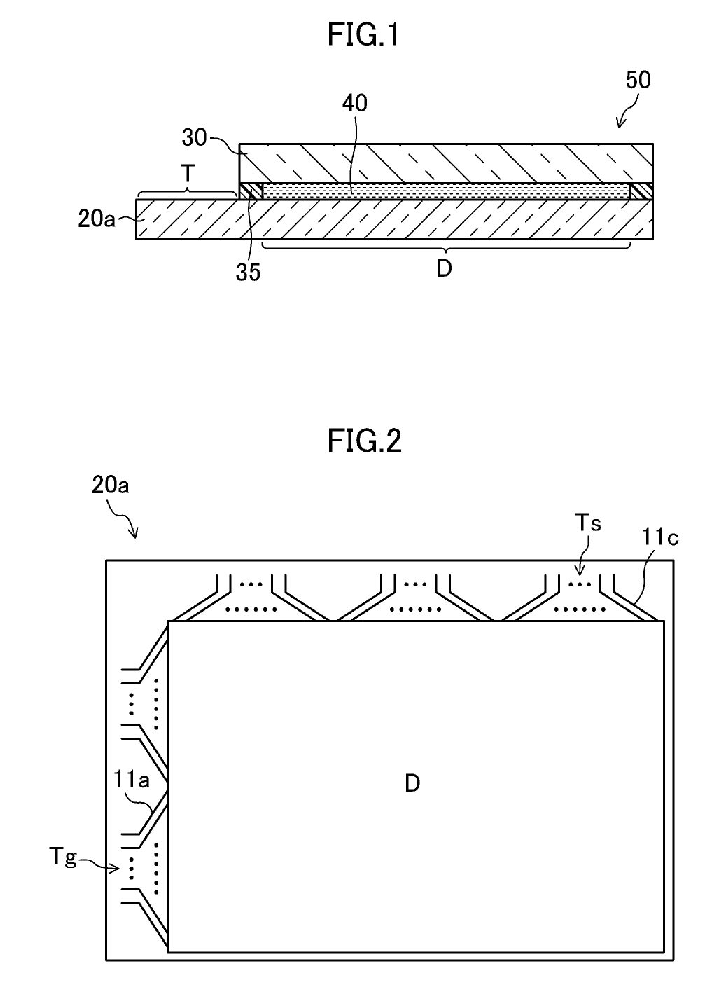

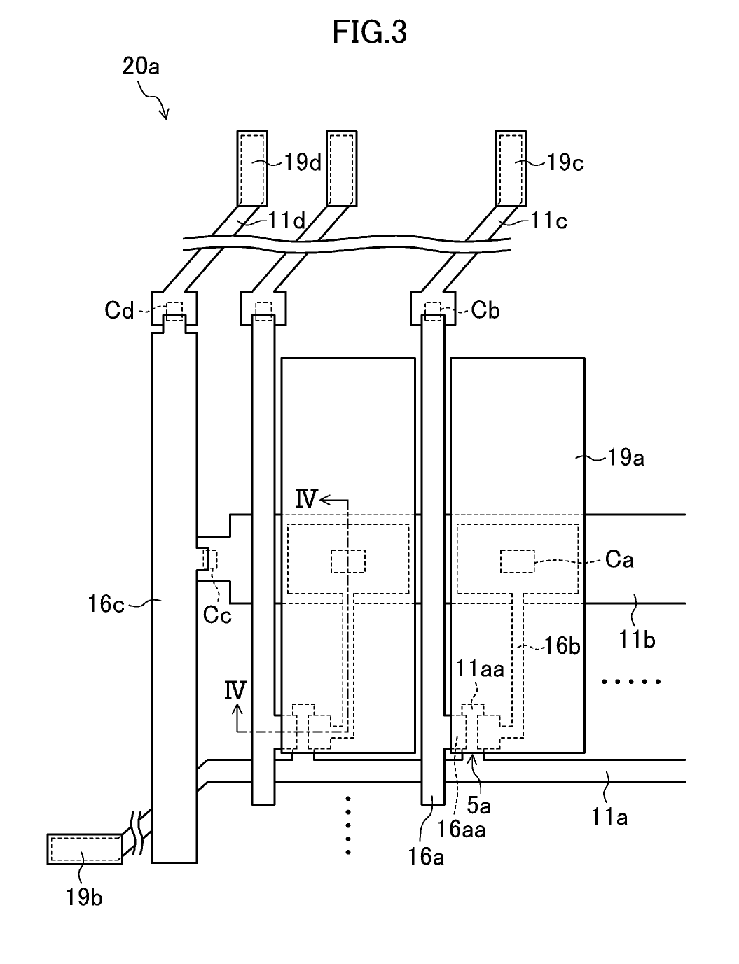

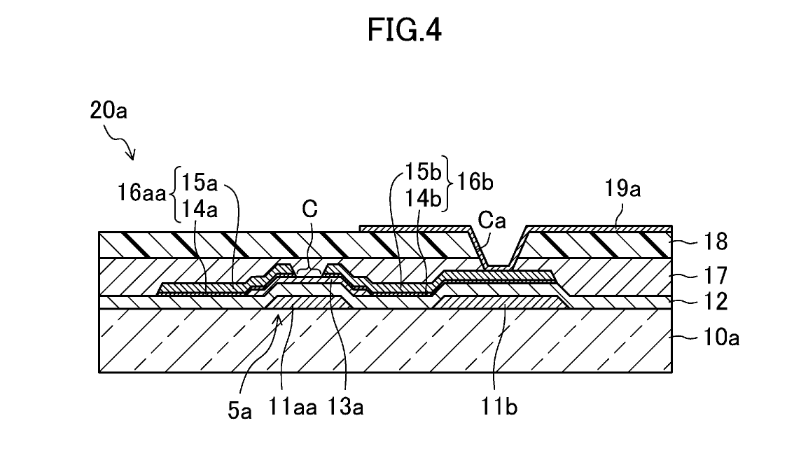

FIGS. 1-7 show an active matrix substrate according to a first embodiment of the present invention and a method for manufacturing the active matrix substrate. Specifically, FIG. 1 is a cross-sectional view showing a liquid crystal display panel 50 including the active matrix substrate 20a of this embodiment. FIG. 2 is a plan view of the active matrix substrate 20a. FIG. 3 is an enlarged plan view of a pixel portion and a terminal portion of the active matrix substrate 20a. FIG. 4 is a cross-sectional view of the active matrix substrate 20a taken along line IV-IV of FIG. 3.

As shown in FIG. 1, the liquid crystal display panel 50 includes the active matrix substrate 20a and a counter substrate 30 which face each other, a liquid crystal layer 40 provided between the active matrix substrate 20a and the counter substrate 30, and a frame-shaped sealing member 35 which is used to bond the active matrix substrate 20a and the counter substrate 30 together and enclose the liquid crystal layer 40 between the active matrix substrate 20a and the counter substrate 30. As shown in FIG. 1, the liquid crystal display panel 50 has a display region D for displaying an image in a portion inside the sealing member 35, and a terminal region T in a portion of the active matrix substrate 20a which protrudes from the counter substrate 30.

As shown in FIGS. 2, 3, and 4, the active matrix substrate 20a includes an insulating substrate 10a, a plurality of scan lines 11a provided on the insulating substrate 10a, extending in parallel to each other in the display region D, a plurality of auxiliary capacitor lines 11b each provided between the corresponding scan lines 11a, extending in parallel to each other in the display region D, a plurality of signal lines 16a extending in a direction perpendicular to the scan lines 11a and in parallel to each other in the display region D, a plurality of TFTs 5a at respective corresponding interconnection portions between the scan lines 11a and the signal lines 16a (i.e., one TFT 5a is provided for each pixel), a protection insulating layer 17 covering the TFTs 5a, an interlayer insulating film 18 covering the protection insulating layer 17, a plurality of pixel electrodes 19a provided and arranged in a matrix on the interlayer insulating layer 18 and connected to the respective corresponding TFTs 5a, and an alignment film (not shown) covering the pixel electrodes 19a.

As shown in FIGS. 2 and 3, the scan line 11a is extended into a gate terminal region Tg of the terminal region T (see FIG. 1) and is connected to the gate terminal 19b in the gate terminal region Tg.

As shown in FIG. 3, the auxiliary capacitor line 11b is connected via an auxiliary capacitor main line 16c and a relay line 11d to an auxiliary capacitor terminal 19d. Here, the auxiliary capacitor main line 16c is connected to the auxiliary capacitor line 11b via a contact hole Cc formed in a gate insulating layer 12 described below, and to the relay line 11d via a contact hole Cd formed in the gate insulating layer 12.

As shown in FIGS. 2 and 3, the signal line 16a is extended as a relay line 11c into a source a source terminal region Ts of the terminal region T (see FIG. 1) and is connected to a source terminal 19c in the source terminal region Ts. Here, as shown in FIG. 3, the signal line 16a is connected to the relay line 11c via a contact hole Cb formed in the gate insulating layer 12.

As shown in FIGS. 3 and 4, the TFT 5a includes a gate electrode 11aa provided on the insulating substrate 10a, the gate insulating layer 12 covering the gate electrode 11aa, an island-like oxide semiconductor layer 13a which is provided on the gate insulating layer 12 over the gate electrode 11aa and has a channel region C, a source electrode 16aa and a drain electrode 16b which are provided on the oxide semiconductor layer 13a, overlapping the gate electrode 11 as and facing each other with the channel region C being interposed between the source electrode 16aa and the drain electrode 16b. Here, the interlayer insulating layer 17 covering the source electrode 16aa and the drain electrode 16b (i.e., the TFT 5a), which is formed of a spin-on glass material, is provided on the channel region C of the oxide semiconductor layer 13a. As shown in FIG. 3, the gate electrode 11aa is a laterally protruding portion of the scan line 11a. As shown in FIG. 3, the source electrode 16aa is a laterally protruding portion of the signal line 16a. As shown in FIG. 4, the source electrode 16aa is formed of a multilayer film of a first conductive layer 14a and a second conductive layer 15a. As shown in FIGS. 3 and 4, the drain electrode 16b is formed of a multilayer film of a first conductive layer 14b and a second conductive layer 15b. The drain electrode 16b is connected to the pixel electrode 19a via a contact hole Ca formed in the multilayer film of the interlayer insulating layer 17 and the interlayer insulating layer 18. The drain electrode 16b is also provided over the auxiliary capacitor line 11b with the gate insulating layer 12 being interposed therebetween, whereby an auxiliary capacitor is formed. The oxide semiconductor layer 13a is formed, for example, of an oxide semiconductor film made of IGZO (In—Ga—Zn—O), etc.

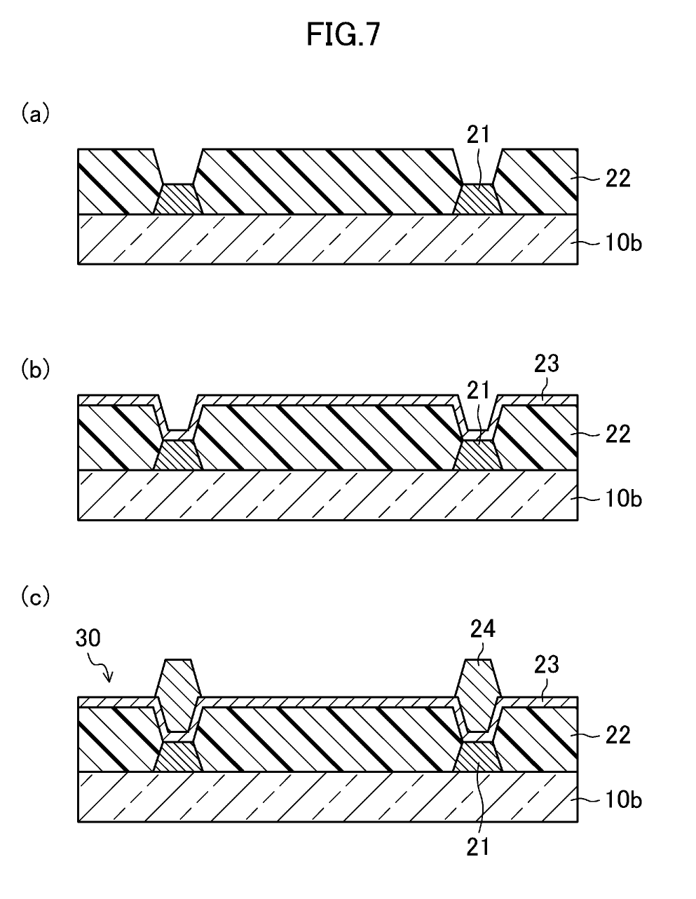

As shown in FIG. 7(c) described below, the counter substrate 30 includes an insulating substrate 10b, a black matrix 21 with a grid pattern provided on the insulating substrate 10b, a color filter layer including color layers 22 (e.g., a red layer, a green layer, and a blue layer, etc.) which are each provided between grid bars of the black matrix 21, a common electrode 23 covering the color filter layer, a photospacer 24 provided on the common electrode 23, and an alignment film (not shown) covering the common electrode 23.

The liquid crystal layer 40 is formed, for example, of a nematic liquid crystal material having electro-optic properties.

In the liquid crystal display panel 50 thus configured, in each pixel P, when a gate signal is sent from a gate driver (not shown) through the scan line 11a to the gate electrode 11aa, so that the TFT 5a is turned on, a source signal is sent from a source driver (not shown) through the signal line 16a to the source electrode 16aa, so that predetermined charge is written through the oxide semiconductor layer 13a and the drain electrode 16b to the pixel electrode 19a. In this case, a potential difference occurs between each pixel electrode 19a of the active matrix substrate 20a and the common electrode 23 of the counter substrate 30, and therefore, a predetermined voltage is applied to the liquid crystal layer 40 (i.e., the liquid crystal capacitor of each pixel) and the auxiliary capacitor connected in parallel to the liquid crystal capacitor. In the liquid crystal display panel 50, in each pixel P, the alignment of the liquid crystal layer 40 is changed, depending on the magnitude of the voltage applied to the liquid crystal layer 40, to adjust the light transmittance of the liquid crystal layer 40, whereby an image is displayed.

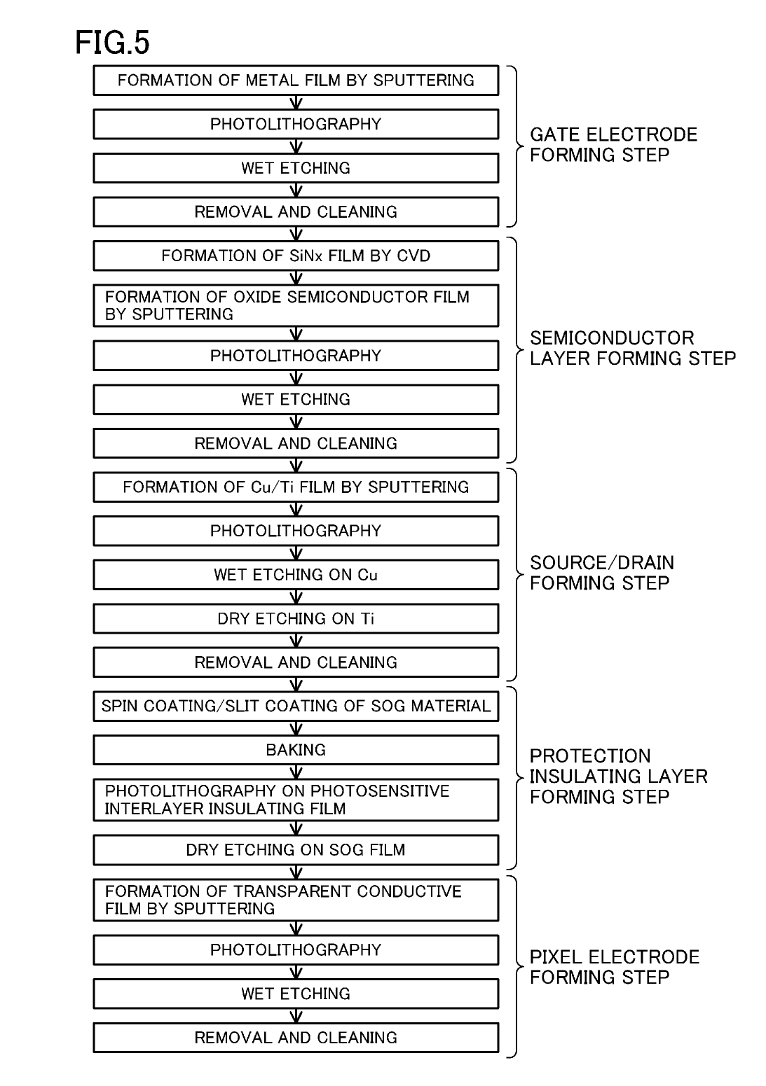

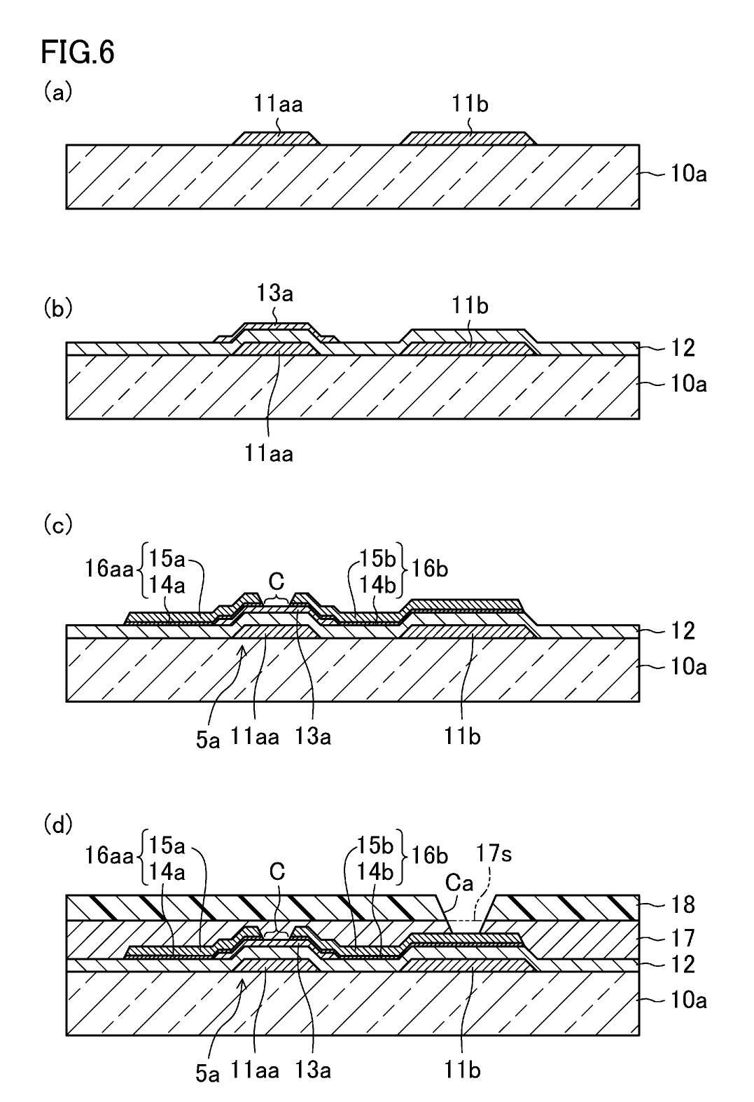

Next, an example method for manufacturing the liquid crystal display panel 50 of this embodiment will be described with reference to FIGS. 5, 6, and 7. FIG. 5 is a flowchart showing a process of manufacturing the active matrix substrate 20a. FIG. 6 is a cross-sectional view for describing the process of manufacturing the active matrix substrate 20a. FIG. 7 is a cross-sectional view for describing a process of manufacturing the counter substrate 30. Note that the manufacturing method of this embodiment includes an active matrix substrate manufacturing process, a counter substrate manufacturing process, and a liquid crystal injecting process.

### <Active Matrix Substrate Manufacturing Step>

Initially, for example, a copper film (thickness: about 200-500 nm), etc., is formed by sputtering on the entire insulating substrate 10a, such as a glass substrate, etc. Thereafter, photolithography, wet etching, and resist removal and cleaning are performed on the copper film. As a result, as shown in FIG. 6(a), the scan line 11a (see FIG. 3), the gate electrode 11aa, the auxiliary capacitor line 11b, and the relay lines 11c and 11d (see FIG. 3) are formed (see a gate electrode forming step shown in FIG. 5). In this embodiment, the copper film having a single-layer structure is illustrated as a metal film which is included in the gate electrode 11aa. Alternatively, for example, a titanium film (thickness: about 30-100 nm) may be provided below the copper film to improve the adhesiveness to the insulating substrate 10a.

Next, for example, a silicon nitride film (thickness: about 200-500 nm) is formed by CVD on the entire substrate on which the scan line 11a, the gate electrode 11aa, the auxiliary capacitor line 11b, and the relay lines 11c and 11d have been formed, to form the gate insulating layer 12. Thereafter, for example, an oxide semiconductor film (thickness: about 30-300 nm) made of IGZO is formed by CVD, and thereafter, photolithography, wet etching, and resist removal and cleaning are performed on the oxide semiconductor film. As a result, as shown in FIG. 6(b), the oxide semiconductor layer 13a is formed (a semiconductor layer forming step shown in FIG. 5). While, in this embodiment, the gate insulating layer 12 has a single-layer structure including a silicon nitride film, the gate insulating film 12 may have a single-layer structure including a silicon oxide film or a multilayer structure including a silicon oxide film (upper layer) and a silicon nitride film (lower layer).

Moreover, for example, a titanium film (thickness: about 30-100 nm) and a copper film (thickness: about 100-400 nm), etc., are successively formed by sputtering on the entire substrate on which the oxide semiconductor layer 13a has been formed. Thereafter, photolithography and wet etching are performed on the copper film, and dry etching and resist removal and cleaning are performed on the titanium film. As a result, as shown in FIG. 6(c), the signal line 16a (see FIG. 3), the source electrode 16aa, the drain electrode 16b, and the auxiliary capacitor main line 16c (see FIG. 3) are formed with the channel region C of the oxide semiconductor layer 13a being exposed (see a source/drain forming step shown in FIG. 5).

Next, on the entire substrate on which the signal line 16a, the source electrode 16aa, the drain electrode 16b, and the auxiliary capacitor main line 16c have been formed, a spin-on glass (SOG) material containing, for example, silanol (Si(OH)₄), alkoxysilane, or organic siloxane resin, etc., as a major component, is applied by spin coating or slit coating, and thereafter, is baked at 350° C., to form an SOG film 17s having a thickness of about 500-3000 nm

Thereafter, on the entire substrate on which the SOG film 17s has been formed, a photosensitive organic insulating film having a thickness of about 1.0-3.0 μm is applied by spin coating or slit coating, and thereafter, exposure and development are performed on the applied film, to form the interlayer insulating layer 18. Thereafter, dry etching is performed on the SOG film 17s exposed through the interlayer insulating layer 18. As a result, as shown in FIG. 6(d), the protection insulating layer 17 is formed (see a protection insulating layer forming step shown in FIG. 5).

Finally, on the entire substrate on which the protection insulating layer 17 and the interlayer insulating layer 18 have been formed, a transparent conductive film such as an indium tin oxide (ITO) film, etc. (thickness: about 50-200 nm) is formed by sputtering, and thereafter, photolithography, wet etching, and resist removal and cleaning are performed on the transparent conductive film. As a result, as shown in FIG. 4, the pixel electrode 19a, the gate terminal 19b, the source terminal 19c, and the auxiliary capacitor terminal 19d (see FIG. 3) are formed (see a pixel electrode forming step shown in FIG. 5).

Thus, the active matrix substrate 20a can be manufactured.

### <Counter Substrate Manufacturing Process>

Initially, for example, a black-colored photosensitive resin is applied on the entire insulating substrate 10b, such as a glass substrate, etc., by spin coating or slit coating, and thereafter, exposure and development are performed on the applied film. As a result, a black matrix 21 having a thickness of about 1.0 μm is formed (see FIG. 7(a)).

Next, on the entire substrate on which the black matrix 21 has been formed, a red-, green-, or blue-colored photosensitive resin is applied by spin coating or slit coating, and thereafter, exposure and development are performed on the applied film, whereby, as shown in FIG. 7(a), a color layer 22 with a selected color (e.g., a red color layer) having a thickness of about 2.0 μm is formed. By repeating a similar process for the two other colors, color layers 22 with the two other colors (e.g., a green color layer and a blue color layer) each having a thickness of about 2.0 μm are formed.

Moreover, a transparent conductive film, such as an ITO film, etc., is deposited by sputtering on the substrate on which the color layers 22 have been formed. As a result, as shown in FIG. 7(b), the common electrode 23 having a thickness of about 50-200 nm is formed.

Finally, on the entire substrate on which the common electrode 23 has been formed, a photosensitive resin is applied by spin coating or split coating, and thereafter, exposure and development are performed on the applied film, whereby, as shown in FIG. 7(c), the photospacer 24 having a thickness of about 4 μm is formed.

Thus, the counter substrate 30 can be manufactured.

### <Liquid Crystal Injecting Process>

Initially, a polyimide resin film is applied by a printing method on each of a surface of the active matrix substrate 20a manufactured in the active matrix substrate manufacturing process and a surface of the counter substrate 30 manufactured in the counter substrate manufacturing process, and thereafter, baking and rubbing are performed on the applied films, to form alignment films.

Next, for example, a frame-shaped sealing member made of an ultraviolet (UV) and thermal curing resin, etc., is printed on the surface of the counter substrate 30 on which the alignment film has been formed, and thereafter, a liquid crystal material is dropped into a region inside the sealing member.

Moreover, the counter substrate 30 on which the liquid crystal material has been dropped, and the active matrix substrate 20a on which the alignment film has been formed, are joined with each other under reduced pressure. Thereafter, the counter substrate 30 and the active matrix substrate 20a thus joined with each other are exposed to the atmosphere so that pressure is applied on the front and rear surfaces of the two-substrate structure.

Thereafter, the sealing member interposed between the counter substrate 30 and the active matrix substrate 20a joined with each other is irradiated with UV light and then heated, whereby the sealing member is cured.

Finally, the two-substrate structure in which the sealing member has been cured is cut by dicing to remove an unnecessary portion.

Thus, the liquid crystal display device 50 of this embodiment can be manufactured.

As described above, according to the active matrix substrate 20a of this embodiment and the method for manufacturing the active matrix substrate 20a, the oxide semiconductor layer 13a is formed in the semiconductor layer forming step, and thereafter, the source electrode 16aa and the drain electrode 16b are formed in the source/drain forming step. Therefore, the active matrix substrate 20a including the TFT 5a in which the oxide semiconductor layer 13a having a relatively small size is formed separately from the formation of the source electrode 16aa and the drain electrode 16b, can be manufactured. In the protection insulating layer forming step, an SOG material is applied by spin coating or slit coating to cover the source electrode 16aa and the drain electrode 16b formed on the oxide semiconductor layer 13a, and baking and patterning are performed on the applied film, to form the protection insulating layer 17 on the channel region C of the oxide semiconductor layer 13a. Therefore, the channel region C of the oxide semiconductor layer 13a is not exposed to plasma, and therefore, the damage to the channel region C of the oxide semiconductor layer 13a can be reduced. When the protection insulating layer 17 is formed in the protection insulating layer forming step, the applied film of the SOG material is baked. During the baking, H₂O occurs due to dehydration polymerization reaction of the SOG material. Here, when patterning is performed on the metal film by dry etching in order to form the source electrode 16aa and the drain electrode 16b in the source/drain forming step, a surface layer of the channel region C of the oxide semiconductor layer 13a is also etched, i.e., the channel region C of the oxide semiconductor layer 13a is damaged. However, when the applied film is baked in the protection insulating layer forming step, H₂O occurs, and therefore, the oxide semiconductor layer 13a is annealed in the presence of H₂O, and therefore, the damage to the channel region C of the oxide semiconductor layer 13a can be satisfactorily repaired. Therefore, by forming the protection insulating layer 17 by applying, baking, and patterning the SOG material, the damage to the channel region C of the oxide semiconductor layer 13a can be reduced and repaired. As a result, an increase in the number of manufacturing steps can be reduced, the damage to the oxide semiconductor layer 13a can be reduced, and satisfactory TFT characteristics can be obtained.

Also, according to the active matrix substrate 20a of this embodiment, the interlayer insulating layer 18 is formed of a photosensitive resin film. Therefore, the interlayer insulating layer 18 having a single-layer structure can be formed without a photoresist, resulting in a reduction in the manufacturing cost of the active matrix substrate 20a.

Also, according to the active matrix substrate 20a of this embodiment, satisfactory TFT characteristics and reliability can be obtained, and therefore, the active matrix substrate 20a can be applied to high-definition display devices, such as a liquid crystal television, etc. In particular, by utilizing the high mobility and reliability of the TFT employing IGZO, the size, resolution, and drive frequency can be improved, and therefore, various circuits, such as a gate driver, a source driver, etc., can be incorporated into the panel.

### Second Embodiment of the Invention

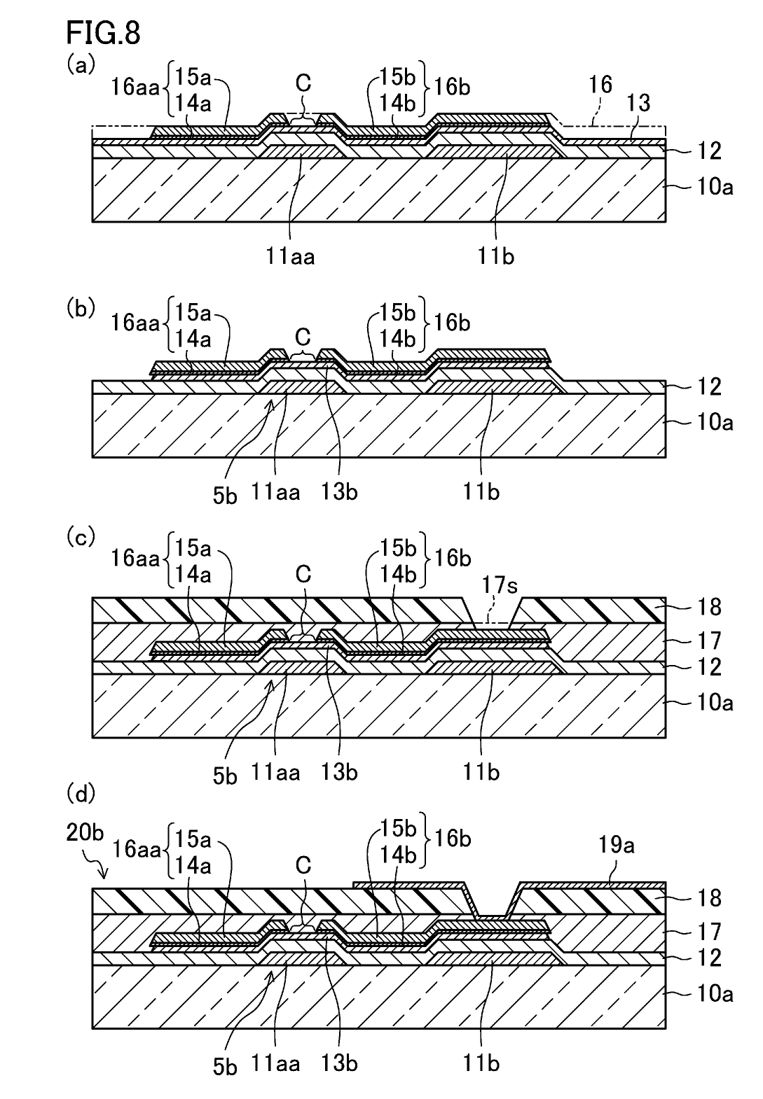

FIG. 8 shows cross-sectional views for describing a process of manufacturing an active matrix substrate 20b of this embodiment. Note that, in embodiments described below, the same parts as those of FIGS. 1-7 are indicated by the same reference characters and will not be described in detail.

In the first embodiment, the active matrix substrate 20a has been illustrated which includes the TFT 5a including the relatively small oxide semiconductor layer 13a. In this embodiment, the active matrix substrate 20b which includes a TFT 5b including a relatively large oxide semiconductor layer 13b will be illustrated.

As shown in FIG. 8(d), the active matrix substrate 20b has the TFT 5b in which the oxide semiconductor layer 13b is formed not only in an upper layer portion of the gate electrode 11aa, but also in entire lower layer portions of the source electrode 16aa and the drain electrode 16b. In other respects, the active matrix substrate 20b has substantially the same configuration as that of the active matrix substrate 20a of the first embodiment.

Next, an example method for manufacturing the active matrix substrate 20b of this embodiment will be described with reference to FIG. 8.

Initially, on the entire substrate on which the gate electrode 11aa and the auxiliary capacitor line 11b, etc., have been formed by performing the gate electrode forming step of the active matrix substrate manufacturing process of the first embodiment, for example, a silicon nitride film (thickness: about 200-500 nm) is formed by CVD to form the gate insulating layer 12. Thereafter, for example, an IGZO oxide semiconductor film 13 (thickness: about 30-300 nm) is continuously formed by CVD. Moreover, for example, a titanium film (thickness: about 30-100 nm) and a copper film (thickness: about 100-400 nm), etc., are successively formed by sputtering to form the metal film 16. Thereafter, photolithography and wet etching are performed on the copper film of the metal film 16, and dry etching and resist removal and cleaning are performed on the titanium film of the metal film 16, whereby, as shown in FIG. 8(a), the source electrode 16aa and the drain electrode 16b are formed, and a region in which the channel region C of the oxide semiconductor layer 13a is to be formed is exposed.

Next, photolithography, wet etching, and resist removal and cleaning are performed on the oxide semiconductor film 13 exposed through the source electrode 16aa and the drain electrode 16b, whereby, as shown in FIG. 8(b), the oxide semiconductor layer 13b is formed (semiconductor layer forming step).

Moreover, on the entire substrate on which the source electrode 16aa, the drain electrode 16b, and the oxide semiconductor layer 13b have been formed, a spin-on glass (SOG) material containing, for example, silanol (Si(OH)₄), alkoxysilane, or organic siloxane resin, etc., as a major component, is applied by spin coating or slit coating, and thereafter, is baked at 350° C., to form an SOG film 17s having a thickness of about 500-3000 nm

Thereafter, on the entire substrate on which the SOG film 17s has been formed, a photosensitive organic insulating film having a thickness of about 1.0-3.0 μm is applied by spin coating or slit coating, and thereafter, exposure and development are performed on the applied film, to form the interlayer insulating layer 18. Moreover, dry etching is performed on the SOG film 17s exposed through the interlayer insulating layer 18. As a result, as shown in FIG. 8(c), the protection insulating layer 17 is formed (protection insulating layer forming step).

Finally, on the entire substrate on which the protection insulating layer 17 and the interlayer insulating layer 18 have been formed, a transparent conductive film such as an indium tin oxide (ITO) film, etc. (thickness: about 50-200 nm) is formed by sputtering, and thereafter, photolithography, wet etching, and resist removal and cleaning are performed on the transparent conductive film. As a result, as shown in FIG. 8(d), the pixel electrode 19a is formed (pixel electrode forming step).

Thus, the active matrix substrate 20b can be manufactured.

As described above, according to the active matrix substrate 20b of this embodiment and the method for manufacturing the active matrix substrate 20b, in the semiconductor layer forming step, after the oxide semiconductor film 13 and the metal film 16 are successively formed, patterning is performed on the oxide semiconductor film 13 which is located below the metal film 16 to form the oxide semiconductor layer 13b, and patterning is performed on the metal film 16 which is located above the oxide semiconductor film 13 to form the source electrode 16aa and the drain electrode 16b. Therefore, the active matrix substrate 20b including the TFT 5b in which the relatively large oxide semiconductor layer 13b is formed in conjunction with the formation of the source electrode 16aa and the drain electrode 16b, can be manufactured. In the protection insulating layer forming step, an SOG material is applied by spin coating or slit coating to cover the source electrode 16aa and the drain electrode 16b formed on the oxide semiconductor layer 13b, and baking and patterning are performed on the applied film, to form the protection insulating layer 17 on the channel region C of the oxide semiconductor layer 13b. Therefore, the channel region C of the oxide semiconductor layer 13b is not exposed to plasma, and therefore, the damage to the channel region C of the oxide semiconductor layer 13b can be reduced. When the protection insulating layer 17 is formed in the protection insulating layer forming step, the applied film of the SOG material is baked. During the baking, H₂O occurs due to dehydration polymerization reaction of the SOG material. Here, when patterning is performed on the metal film 16 by dry etching in order to form the source electrode 16aa and the drain electrode 16b in the source/drain forming step, a surface layer of the channel region C of the oxide semiconductor layer 13b is also etched, i.e., the channel region C of the oxide semiconductor layer 13b is damaged. However, when the applied film is baked in the protection insulating layer forming step, H₂O occurs, and therefore, the oxide semiconductor layer 13b is annealed in the presence of H₂O, and therefore, the damage to the channel region C of the oxide semiconductor layer 13b can be satisfactorily repaired. Thus, by forming the protection insulating layer 17 by applying, baking, and patterning the SOG material, the damage to the channel region C of the oxide semiconductor layer 13b can be reduced and repaired. As a result, an increase in the number of manufacturing steps can be reduced, the damage to the oxide semiconductor layer 13b can be reduced, and satisfactory TFT characteristics can be obtained.

### Third Embodiment of the Invention

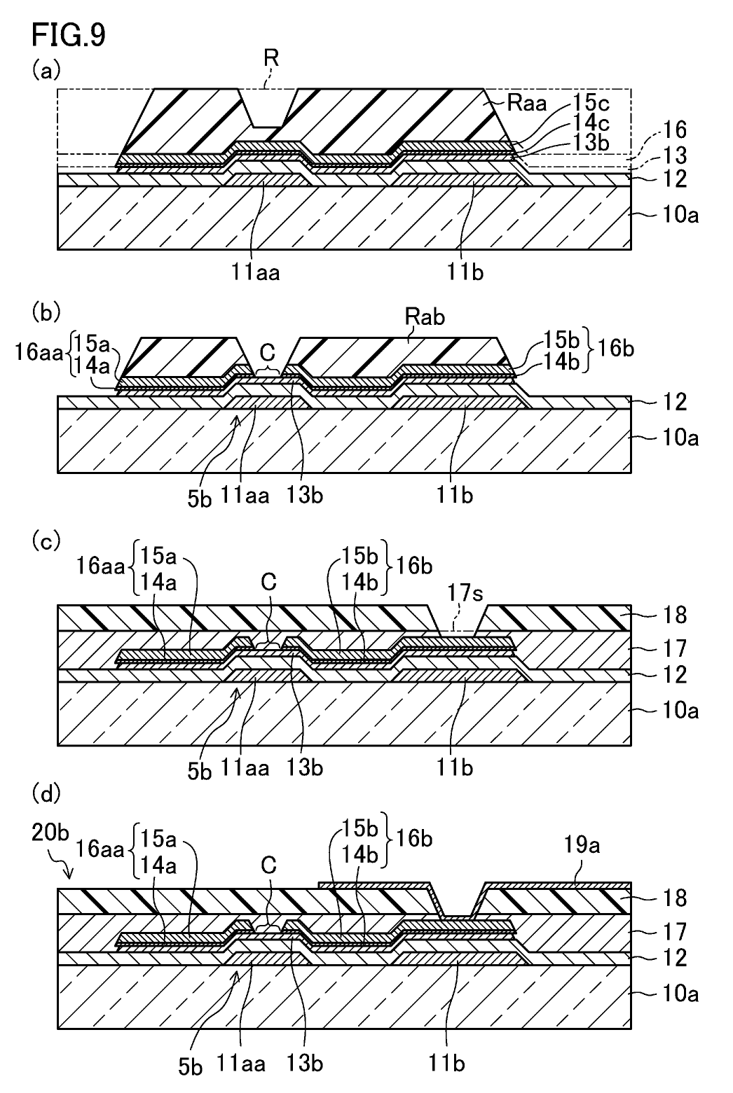

FIG. 9 shows cross-sectional views for describing a process of manufacturing an active matrix substrate 20b according to this embodiment.

In the second embodiment, the method of manufacturing the active matrix substrate 20b including the TFT 5b including the relatively large oxide semiconductor layer 13b using five photomasks has been illustrated. In this embodiment, a method of manufacturing the active matrix substrate 20b using four photomasks will be illustrated.

Specifically, an example method for manufacturing the active matrix substrate 20b of this embodiment will be described with reference to FIG. 9.

Initially, as in the method for manufacturing the active matrix substrate 20b of the second embodiment, a silicon nitride film (12) and the oxide semiconductor film 13, and the metal film 16, are successively formed by CVD and sputtering, respectively, on the entire substrate on which the gate electrode 11aa and the auxiliary capacitor line 11b, etc., have been formed. A photosensitive resin film R is formed on the metal film 16. Thereafter, the photosensitive resin film R is exposed to light, for example, via a halftone or graytone photomask having transparent, opaque, and translucent portions, and thereafter, development is performed, to form a resist pattern Raa (see FIG. 9(a)) having a relatively thin portion in which the channel region C is to be formed and a relatively thick portion in which the source electrode 16aa and the drain electrode 16b are to be formed. Thereafter, as shown in FIG. 9(a), wet etching is performed on the copper film of the metal film 16 exposed through the resist pattern Raa, and dry etching is performed on the titanium film of the metal film 16, to form a first conductive layer 14c and a second conductive layer 15c. Moreover, wet etching is performed on the oxide semiconductor film 13 to form the oxide semiconductor layer 13b.

Next, the thickness of the resist pattern Raa is decreased by ashing to remove the relatively thin portion of the resist pattern Raa, whereby a resist pattern Rab (see FIG. 9(b)) is formed. Thereafter, wet etching is performed on the second conductive layer 15c exposed through the resist pattern Rab, and dry etching, and removal and cleaning of the resist pattern Rab, are performed on the first conductive layer 14c. As a result, as shown in FIG. 9(b), the source electrode 16aa and the drain electrode 16b are formed, and the channel region C of the oxide semiconductor layer 13b is exposed (semiconductor layer forming step).

Moreover, on the entire substrate on which the source electrode 16aa, the drain electrode 16b, and the oxide semiconductor layer 13b have been formed, a spin-on glass (SOG) material containing, for example, silanol (Si(OH)₄), alkoxysilane, or organic siloxane resin, etc., as a major component, is applied by spin coating or slit coating, and thereafter, is baked at 350° C., to form an SOG film 17s having a thickness of about 500-3000 nm Thereafter, on the entire substrate on which the SOG film 17s has been formed, a photosensitive organic insulating film having a thickness of about 1.0-3.0 μm is applied by spin coating or slit coating, and thereafter, exposure and development are performed on the applied film, to form the interlayer insulating layer 18. Thereafter, dry etching is performed on the SOG film 17s exposed through the interlayer insulating layer 18. As a result, as shown in FIG. 9(c), the protection insulating layer 17 is formed (protection insulating layer forming step).

Finally, on the entire substrate on which the protection insulating layer 17 and the interlayer insulating layer 18 have been formed, a transparent conductive film such as an ITO film (thickness: about 50-200 nm), etc. is formed by sputtering, and thereafter, photolithography, wet etching, and resist removal and cleaning are performed on the transparent conductive film. As a result, as shown in FIG. 9(d), the pixel electrode 19a is formed (pixel electrode forming step).

Thus, the active matrix substrate 20b can be manufactured.

As described above, according to the active matrix substrate 20b of this embodiment and the method for manufacturing the active matrix substrate 20b, as in the above embodiments, the protection insulating layer 17 made of an SOG material is provided on the channel region C of the oxide semiconductor layer 13b. As a result, an increase in the number of manufacturing steps can be reduced, the damage to the oxide semiconductor layer 13b can be reduced, and satisfactory TFT characteristics can be obtained.

Also, according to the method for manufacturing the active matrix substrate 20b of this embodiment, in the semiconductor layer forming step, a single halftone or graytone photomask which allows half exposure is used to form, on the metal film 16, the resist pattern Raa which has a relatively thin portion in which the channel region C of the oxide semiconductor layer 13b is to be formed and a relatively thick portion in which the source electrode 16aa and the drain electrode 16b are to be formed. The resist pattern Raa is used to form the oxide semiconductor layer 13b. The resist pattern Rab which is obtained by decreasing the thickness of the resist pattern Raa is used to form the source electrode 16aa and the drain electrode 16b. As a result, the manufacturing cost of the active matrix substrate 20b can be reduced.

### Fourth Embodiment of the Invention

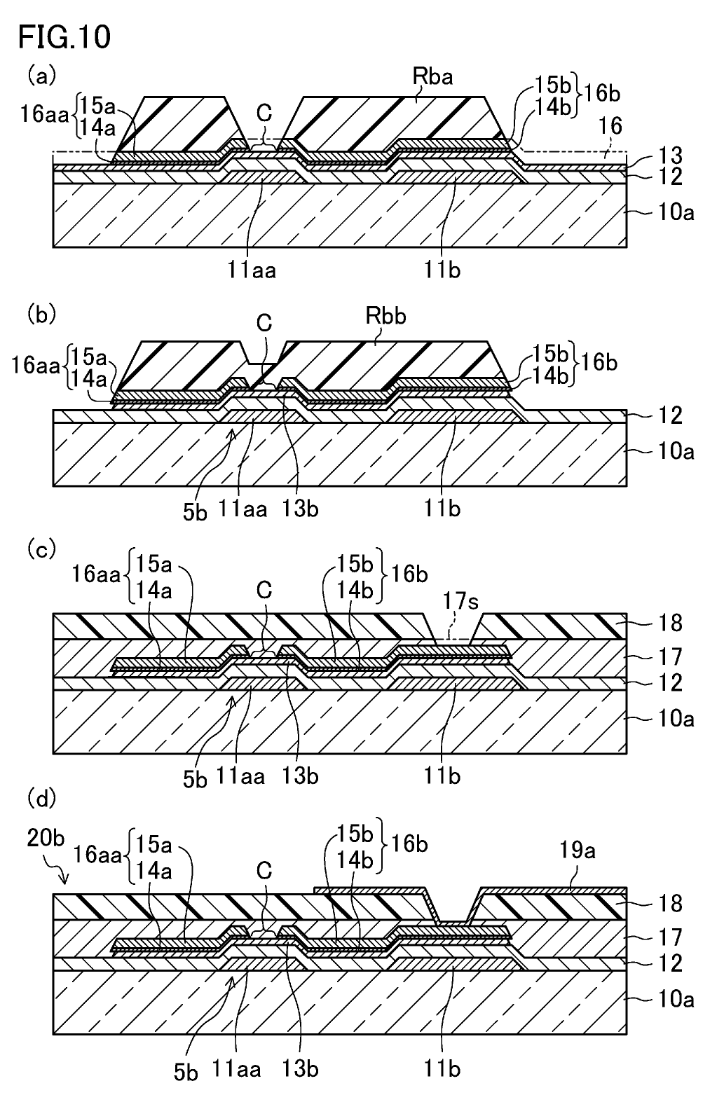

FIG. 10 shows cross-sectional views for describing a process of manufacturing an active matrix substrate 20b according to this embodiment.

In the third embodiment, the method of manufacturing the active matrix substrate 20b using four photomasks in which half exposure is performed has been illustrated. In this embodiment, a method of manufacturing the active matrix substrate 20b using four photomasks, but without half exposure, will be illustrated.

Specifically, an example method for manufacturing the active matrix substrate 20b of this embodiment will be described with reference to FIG. 10.

Initially, as in the method for manufacturing the active matrix substrate 20b of the second embodiment, a silicon nitride film (12) and the oxide semiconductor film 13, and the metal film 16, are successively formed by CVD and sputtering, respectively, on the entire substrate on which the gate electrode 11aa and the auxiliary capacitor line 11b, etc., have been formed. A resist pattern Rba (see FIG. 10(a)) is formed on the metal film 16 to cover portions of the metal film 16 in which the source electrode 16aa and the drain electrode 16b are to be formed. Thereafter, as shown in FIG. 10(a), wet etching is performed on the copper film of the metal film 16 exposed through the resist pattern Rba, and dry etching is performed on the titanium film of the metal film 16, to form the source electrode 16aa and the drain electrode 16b and expose a region of the oxide semiconductor film 13 in which the channel region C is to be formed.

Next, reflowing is performed on the resist pattern Rba to form a resist pattern Rbb (see FIG. 10(b)) which covers the region of the oxide semiconductor film 13 in which the channel region C is to be formed, and thereafter, wet etching, and removal and cleaning of the resist pattern Rbb, are performed on the oxide semiconductor film 13 exposed through the resist pattern Rbb. As a result, as shown in FIG. 10(b), the oxide semiconductor layer 13b is formed (semiconductor layer forming step).

Moreover, on the entire substrate on which the source electrode 16aa, the drain electrode 16b, and the oxide semiconductor layer 13b have been formed, a spin-on glass (SOG) material containing, for example, silanol (Si(OH)₄), alkoxysilane, or organic siloxane resin, etc., as a major component, is applied by spin coating or slit coating, and thereafter, is baked at 350° C., to form an SOG film 17s having a thickness of about 500-3000 nm

Thereafter, on the entire substrate on which the SOG film 17s has been formed, a photosensitive organic insulating film having a thickness of about 1.0-3.0 μm is applied by spin coating or slit coating, and thereafter, exposure and development are performed on the applied film, to form the interlayer insulating layer 18. Thereafter, dry etching is performed on the SOG film 17s exposed through the interlayer insulating layer 18. As a result, as shown in FIG. 10(c), the protection insulating layer 17 is formed (protection insulating layer forming step).

Finally, on the entire substrate on which the protection insulating layer 17 and the interlayer insulating layer 18 have been formed, a transparent conductive film such as an ITO film (thickness: about 50-200 nm), etc. is formed by sputtering, and thereafter, photolithography, wet etching, and resist removal and cleaning are performed on the transparent conductive film. As a result, as shown in FIG. 10(d), the pixel electrode 19a is formed (pixel electrode forming step).

Thus, the active matrix substrate 20b can be manufactured. As described above, according to the active matrix substrate 20b of this embodiment and the method for manufacturing the active matrix substrate 20b, as in the above embodiments, the protection insulating layer 17 made of an SOG material is provided on the channel region C of the oxide semiconductor layer 13b. As a result, an increase in the number of manufacturing steps can be reduced, the damage to the oxide semiconductor layer 13b can be reduced, and satisfactory TFT characteristics can be obtained.

Also, according to the method for manufacturing the active matrix substrate 20b of this embodiment, in the semiconductor layer forming step, a single photomask is used to form, on the metal film 16, the resist pattern Rba which covers portions of the metal film 16 in which the source electrode 16aa and the drain electrode 16b are to be formed. The resist pattern Rba is used to form the source electrode 16aa and the drain electrode 16b.

Reflowing is performed on the resist pattern Rba to form the resist pattern Rbb, and the resist pattern Rbb is used to form the oxide semiconductor layer 13b. As a result, the manufacturing cost of the active matrix substrate 20b can be reduced.

### Fifth Embodiment of the Invention

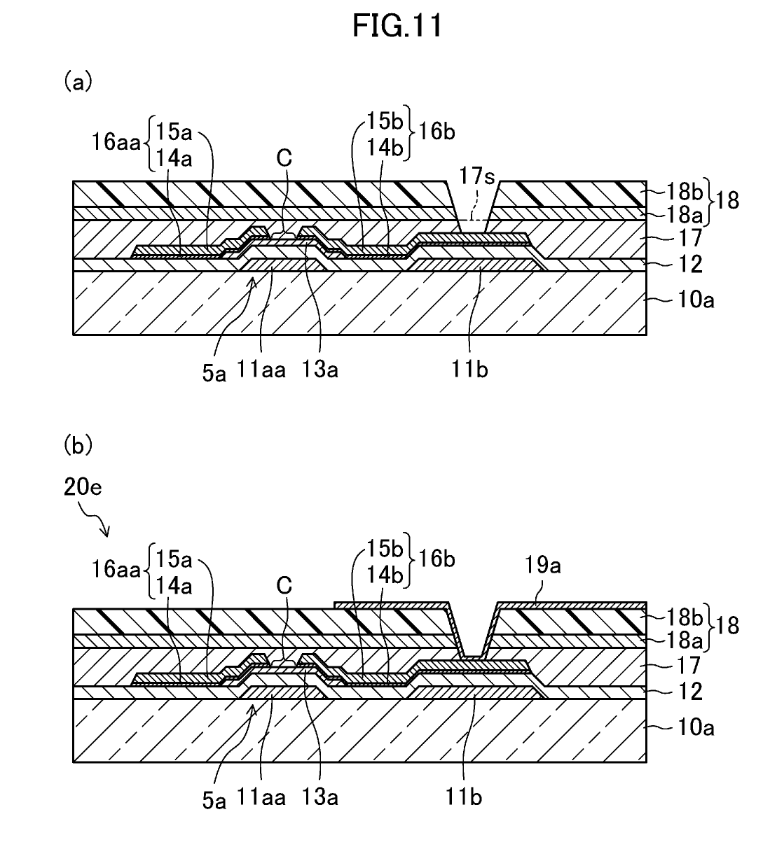

FIG. 11 shows cross-sectional views for describing a process of manufacturing an active matrix substrate 20e according to this embodiment.

In the above embodiments, the active matrix substrate including the interlayer insulating layer 18 having a single-layer structure has been illustrated. In this embodiment, an active matrix substrate 20e including an interlayer insulating layer 18 having a multilayer structure will be illustrated.

As shown in FIG. 11(b), the active matrix substrate 20e includes an interlayer insulating layer 18 including a first interlayer insulating layer 18a and a second interlayer insulating layer 18b. In other respects, the active matrix substrate 20e has substantially the same configuration as that of the active matrix substrate 20a of the first embodiment. Here, the first interlayer insulating layer 18a is formed of a CVD film. The second interlayer insulating layer 18b is formed of a photosensitive resin film.

Next, an example method for manufacturing the active matrix substrate 20e of this embodiment will be described with reference to FIG. 11.

Initially, on the entire substrate on which the source electrode 16aa and the drain electrode 16b, etc., have been formed by performing the source/drain forming step of the active matrix substrate manufacturing process of the first embodiment, a spin-on glass (SOG) material containing, for example, silanol (Si(OH)₄), alkoxysilane, or organic siloxane resin, etc., as a major component, is applied by spin coating or slit coating, and thereafter, is baked at 350° C., to form an SOG film 17s having a thickness of about 500-3000 nm.

Next, on the entire substrate on which the SOG film 17s has been formed, a CVD film such as a silicon nitride film (thickness: about 100-700 nm), etc. is formed by CVD, and a photosensitive organic insulating film having a thickness of about 1.0-3.0 μm is applied by spin coating or slit coating, and thereafter, exposure and development are performed on the applied film, to form the second interlayer insulating layer 18b. Moreover, dry etching is performed on the CVD film exposed through the second interlayer insulating layer 18b and the SOG film 17s located below the CVD film, whereby, as shown in FIG. 11(a), the protection insulating layer 17 and the first interlayer insulating layer 18a are formed (see the protection insulating layer forming step). While, in this embodiment, the CVD film having a single-layer structure including a silicon nitride film has been illustrated, the CVD film may have a single-layer structure including a silicon oxide film or a multilayer structure including a silicon oxide film (upper layer) and a silicon nitride film (lower layer), for example.

Finally, on the entire substrate on which the protection insulating layer 17 and the first and second interlayer insulating layers 18a and 18b have been formed, a transparent conductive film such as an ITO film (thickness: about 50-200 nm), etc. is formed by sputtering, and thereafter, photolithography, wet etching, and resist removal and cleaning are performed on the transparent conductive film. As a result, as shown in FIG. 11(b), the pixel electrode 19a is formed (pixel electrode forming step).

Thus, the active matrix substrate 20e can be manufactured.

As described above, according to the active matrix substrate 20e of this embodiment and the method for manufacturing the active matrix substrate 20e, as in the above embodiments, the protection insulating layer 17 made of an SOG material is provided on the channel region C of the oxide semiconductor layer 13a. As a result, an increase in the number of manufacturing steps can be reduced, the damage to the oxide semiconductor layer 13a can be reduced, and satisfactory TFT characteristics can be obtained.

Also, according to the method for manufacturing the active matrix substrate 20e of this embodiment, the interlayer insulating layer 18 is formed of a multilayer film in which the CVD film and the photosensitive resin film are successively stacked. Therefore, the interlayer insulating layer 18 having a multilayer structure can be formed without using a photoresist. As a result, the manufacturing cost of the active matrix substrate 20e can be reduced.

### Sixth Embodiment of the Invention

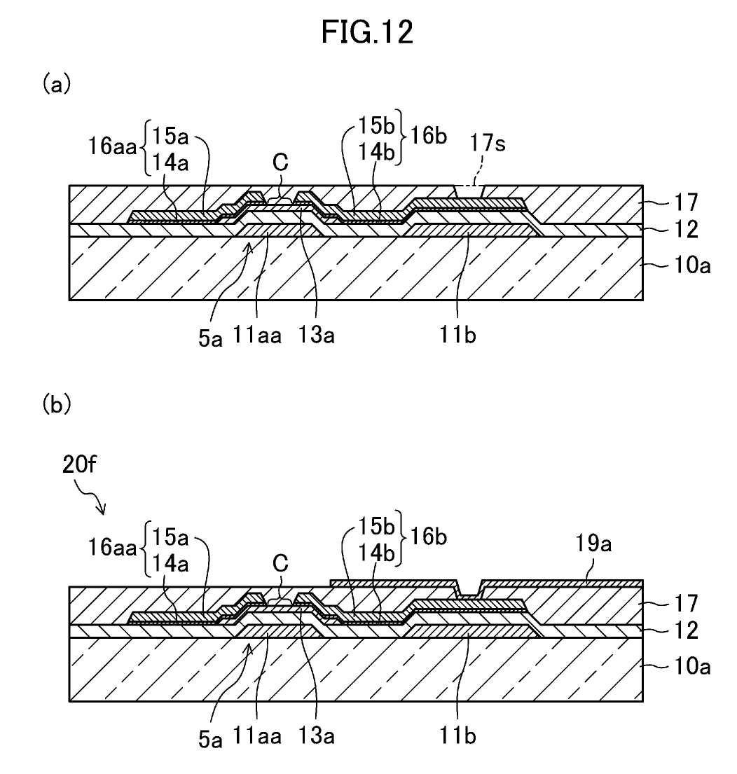

FIG. 12 shows cross-sectional views for describing a process of manufacturing an active matrix substrate 20f according to this embodiment.

In the above embodiments, the active matrix substrate in which the protection insulating layer 17 and the interlayer insulating layer 18 are provided between the TFT and the pixel electrode 19a has been illustrated. In this embodiment, an active matrix substrate 20f in which the interlayer insulating layer 18 is removed will be illustrated.

As shown in FIG. 12(b), the active matrix substrate 20f includes only the protection insulating layer 17 between the TFT 5a and the pixel electrode 19a. In other respects, the active matrix substrate 20f has substantially the same configuration as that of the active matrix substrate 20a of the first embodiment.

Next, an example method for manufacturing the active matrix substrate 20f of this embodiment will be described with reference to FIG. 12.

Initially, on the entire substrate on which the source electrode 16aa and the drain electrode 16b, etc., have been formed by performing the source/drain forming step of the active matrix substrate manufacturing process of the first embodiment, a spin-on glass (SOG) material containing, for example, silanol (Si(OH)₄), alkoxysilane, or organic siloxane resin, etc., as a major component, is applied by spin coating or slit coating, and thereafter, is baked at 350° C., to form an SOG film 17s having a thickness of about 500-3000 nm. Next, photolithography, dry etching, and resist removal and cleaning are performed on the SOG film 17s, whereby, as shown in FIG. 12(a), the protection insulating layer 17 is formed (see the protection insulating layer forming step).

Finally, on the entire substrate on which the protection insulating layer 17 has been formed, a transparent conductive film such as an ITO film (thickness: about 50-200 nm), etc. is formed by sputtering, and thereafter, photolithography, wet etching, and resist removal and cleaning are performed on the transparent conductive film. As a result, as shown in FIG. 12(b), the pixel electrode 19a is formed (pixel electrode forming step).

Thus, the active matrix substrate 20f can be manufactured.

As described above, according to the active matrix substrate 20f of this embodiment and the method for manufacturing the active matrix substrate 20f, as in the above embodiments, the protection insulating layer 17 made of an SOG material is provided on the channel region C of the oxide semiconductor layer 13a. As a result, an increase in the number of manufacturing steps can be reduced, the damage to the oxide semiconductor layer 13a can be reduced, and satisfactory TFT characteristics can be obtained.

Also, according to the method for manufacturing the active matrix substrate 20f of this embodiment, the pixel electrode 19a is provided on the protection insulating layer 17, and therefore, the insulating layer between the pixel electrode 19a and the TFT 5a has a single-layer structure including the protection insulating layer 17. As a result, the manufacturing cost of the active matrix substrate 20f can be reduced.

### Seventh Embodiment of the Invention

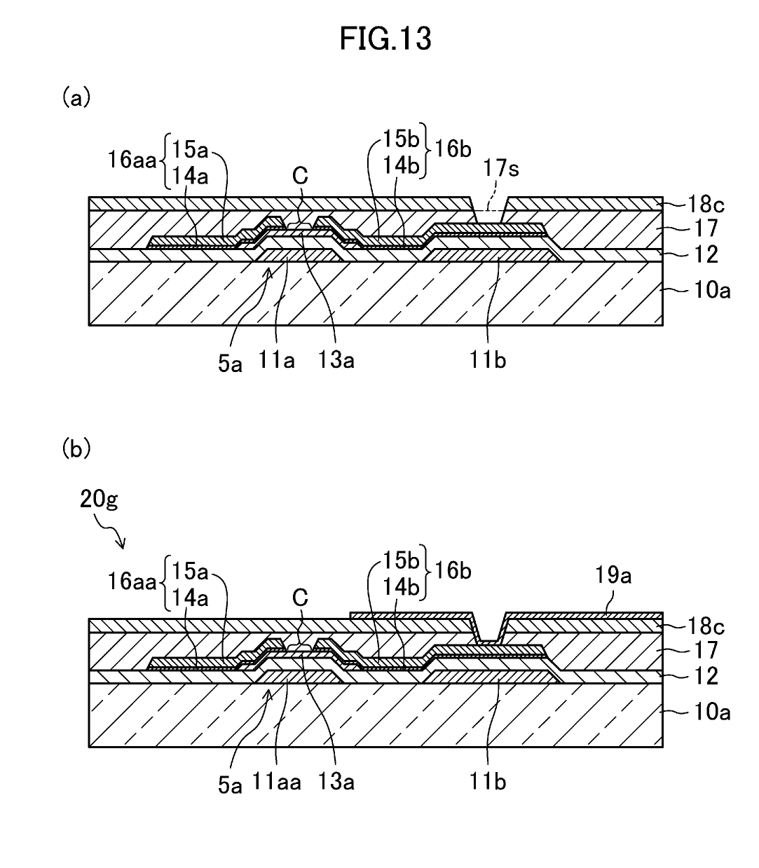

FIG. 13 shows cross-sectional views for describing a process of manufacturing an active matrix substrate 20g according to this embodiment.

In the first to fifth embodiments, the active matrix substrate in which the interlayer insulating layer 18 (the second interlayer insulating layer 18b) is formed of a photosensitive resin film has been illustrated. In this embodiment, the active matrix substrate 20g including an interlayer insulating layer 18c formed of a CVD film will be illustrated.

As shown in FIG. 13(b), the active matrix substrate 20g includes the interlayer insulating layer 18c formed of a CVD film. In other respects, the active matrix substrate 20g has substantially the same configuration as that of the active matrix substrate 20a of the first embodiment.

Next, an example method for manufacturing the active matrix substrate 20g of this embodiment will be described with reference to FIG. 13.

Initially, on the entire substrate on which the source electrode 16aa and the drain electrode 16b, etc., have been formed by performing the source/drain forming step of the active matrix substrate manufacturing process of the first embodiment, a spin-on glass (SOG) material containing, for example, silanol (Si(OH)₄), alkoxysilane, or organic siloxane resin, etc., as a major component, is applied by spin coating or slit coating, and thereafter, is baked at 350° C., to form an SOG film 17s having a thickness of about 500-3000 nm.

Next, on the entire substrate on which the SOG film 17s has been formed, a CVD film such as a silicon nitride film (thickness: about 100-700 nm), etc. is formed by CVD.

Thereafter, photolithography, dry etching, resist removal and cleaning are performed on the CVD film to form the interlayer insulating layer 18c. Moreover, dry etching is performed on the SOG film 17s exposed through the interlayer insulating layer 18c, whereby, as shown in FIG. 13(a), the protection insulating layer 17 is formed (see the protection insulating layer forming step). While, in this embodiment, the CVD film having a single-layer structure including a silicon nitride film has been illustrated, the CVD film may have a single-layer structure including a silicon oxide film or a multilayer structure including a silicon oxide film (upper layer) and a silicon nitride film (lower layer), for example.

Finally, on the entire substrate on which the protection insulating layer 17 and the interlayer insulating layer 18c have been formed, a transparent conductive film such as an ITO film (thickness: about 50-200 nm), etc. is formed by sputtering, and thereafter, photolithography, wet etching, and resist removal and cleaning are performed on the transparent conductive film. As a result, as shown in FIG. 13(b), the pixel electrode 19a is formed (pixel electrode forming step).

Thus, the active matrix substrate 20g can be manufactured.

As described above, according to the active matrix substrate 20g of this embodiment and the method for manufacturing the active matrix substrate 20g, as in the above embodiments, the protection insulating layer 17 made of an SOG material is provided on the channel region C of the oxide semiconductor layer 13a. As a result, an increase in the number of manufacturing steps can be reduced, the damage to the oxide semiconductor layer 13a can be reduced, and satisfactory TFT characteristics can be obtained.

### Eighth Embodiment of the Invention

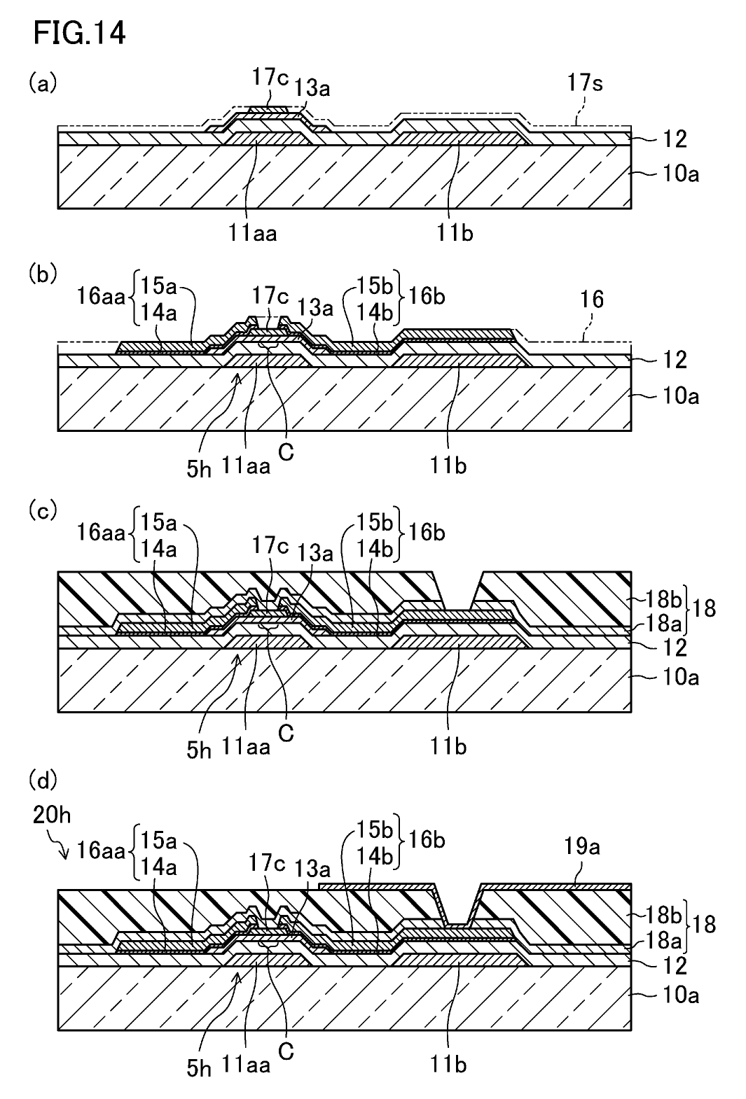

FIG. 14 shows cross-sectional views for describing a process of manufacturing an active matrix substrate 20h according to this embodiment.

In the above embodiments, the active matrix substrate in which the protection insulating layer 17 covers not only the channel region C of the oxide semiconductor layer but also the source electrode 16aa and the drain electrode 16b, has been illustrated. In this embodiment, the active matrix substrate 20h in which a protection insulating layer 17c is provided only on the oxide semiconductor layer 13a will be illustrated.

As shown in FIG. 14(d), the active matrix substrate 20h includes a TFT 5h in which the protection insulating layer 17c is provided between the oxide semiconductor layer 13a, and the source electrode 16aa and the drain electrode 16b, and is covered by an interlayer insulating layer 18 including a first interlayer insulating layer 18a and a second interlayer insulating layer 18b. In other respects, the active matrix substrate 20h has substantially the same configuration as that of the active matrix substrate 20a of the first embodiment.

Next, an example method for manufacturing the active matrix substrate 20h of this embodiment will be described with reference to FIG. 14.

Initially, on the entire substrate on which the oxide semiconductor layer 13a has been formed by performing the source/drain forming step of the active matrix substrate manufacturing process of the first embodiment, a spin-on glass (SOG) material containing, for example, silanol (Si(OH)₄), alkoxysilane, or organic siloxane resin, etc., as a major component, is applied by spin coating or slit coating, and thereafter, is baked at 350° C., to form an SOG film 17s having a thickness of about 500-3000 nm Moreover, photolithography, dry etching, and resist removal and cleaning are performed on the SOG film 17s, whereby, as shown in FIG. 14(a), the protection insulating layer 17c is formed (protection insulating layer forming step).

Next, on the entire substrate on which the protection insulating layer 17c has been formed, for example, a titanium film (thickness: about 30-100 nm) and a copper film (thickness: about 100-400 nm), etc., are successively formed by sputtering to form the metal film 16. Thereafter, photolithography and wet etching are performed on the copper film of the metal film 16, and dry etching and resist removal and cleaning are performed on the titanium film of the metal film 16, whereby, as shown in FIG. 14(b), the source electrode 16aa and the drain electrode 16b are formed (source/drain forming step).

Next, on the entire substrate on which the source electrode 16aa and the drain electrode 16b have been formed, a CVD film such as a silicon nitride film (thickness: about 100-700 nm), etc. is formed by CVD, and a photosensitive organic insulating film having a thickness of about 1.0-3.0 μm is applied by spin coating or slit coating, and thereafter, exposure and development are performed on the applied film, to form the second interlayer insulating layer 18b. Thereafter, dry etching is performed on the CVD film exposed through the second interlayer insulating layer 18b, whereby, as shown in FIG. 14(c), the first interlayer insulating layer 18a is formed (interlayer insulating layer forming step).

Finally, on the entire substrate on which the first and second interlayer insulating layers 18a and 18b have been formed, a transparent conductive film such as an ITO film (thickness: about 50-200 nm), etc. is formed by sputtering, and thereafter, photolithography, wet etching, and resist removal and cleaning are performed on the transparent conductive film. As a result, as shown in FIG. 14(d), the pixel electrode 19a is formed (pixel electrode forming step).

Thus, the active matrix substrate 20h can be manufactured.

As described above, according to the active matrix substrate 20h of this embodiment and the method for manufacturing the active matrix substrate 20h, the oxide semiconductor layer 13a is formed in the semiconductor layer forming step, and thereafter, the protection insulating layer forming step is performed before the source electrode 16aa and the drain electrode 16b are formed in the source/drain forming step. Therefore, the active matrix substrate 20h including the TFT 5h in which the oxide semiconductor layer 13a having a relatively small size is formed separately from the formation of the source electrode 16aa and the drain electrode 16b, can be manufactured. In the protection insulating layer forming step, an SOG material is applied by spin coating or slit coating to cover the oxide semiconductor layer 13a, and baking and patterning are performed on the applied film, to form the protection insulating layer 17c on the channel region C of the oxide semiconductor layer 13a. Therefore, the channel region C of the oxide semiconductor layer 13a is not exposed to plasma, and therefore, the damage to the channel region C of the oxide semiconductor layer 13a can be reduced. Also, when patterning is performed on the metal film 16 by dry etching in order to form the source electrode 16aa and the drain electrode 16b in the source/drain forming step, the protection insulating layer 17c on the channel region C of the oxide semiconductor layer 13a functions as an etch stopper for the oxide semiconductor layer 13a, and therefore, the damage to the channel region C of the oxide semiconductor layer 13a can be reduced. Also, when the protection insulating layer 17c is formed in the protection insulating layer forming step, the applied film of the SOG material is baked. During the baking, H₂O occurs due to dehydration polymerization reaction of the SOG material. Therefore, when the applied film is baked in the protection insulating layer forming step, H₂O occurs, and therefore, the oxide semiconductor layer 13a is annealed in the presence of H₂O. Therefore, even if the channel region C of the oxide semiconductor layer 13a is damaged, the damage to the channel region C of the oxide semiconductor layer 13a can be satisfactorily repaired. Thus, by forming the protection insulating layer 17c by applying, baking, and patterning the SOG material, the damage to the channel region C of the oxide semiconductor layer 13a can be reduced and repaired. As a result, an increase in the number of manufacturing steps can be reduced, the damage to the oxide semiconductor layer 13a can be reduced, and satisfactory TFT characteristics can be obtained.

Also, according to the active matrix substrate 20h of this embodiment, the protection insulating layer 17c is provided between the source electrode 16aa and the drain electrode 16b, and the oxide semiconductor layer 13a. Therefore, the protection insulating layer 17c functions as an etch stopper when the source electrode 16aa and the drain electrode 16b are formed, and therefore, the damage to a surface layer of the oxide semiconductor layer 13a can be reduced during etching which is performed when the source electrode 16aa and the drain electrode 16b are formed, resulting in an improvement in TFT characteristics.

### Ninth Embodiment of the Invention

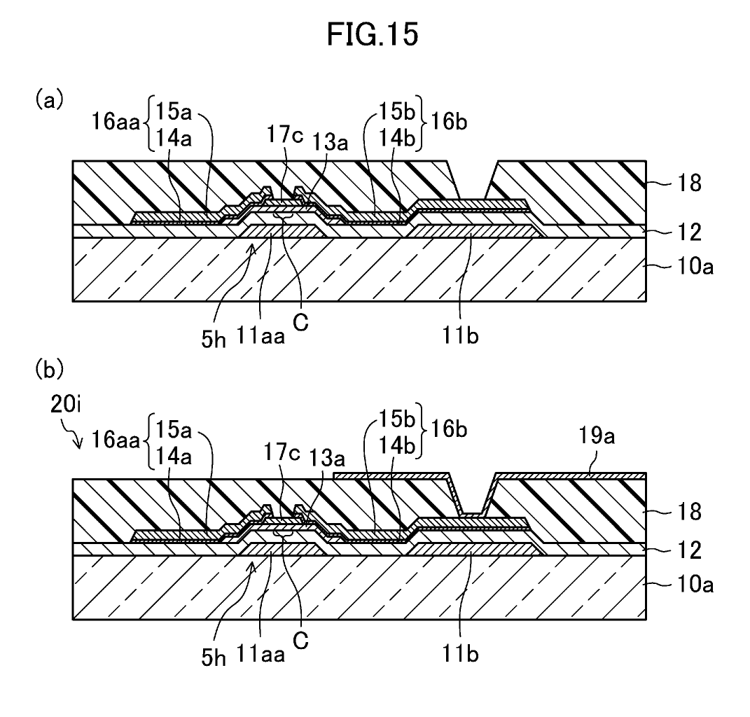

FIG. 15 shows cross-sectional views for describing a process of manufacturing an active matrix substrate 20i according to this embodiment.

In the eighth embodiment, the active matrix substrate 20h in which the interlayer insulating layer 18 covering the TFT 5h in which the protection insulating layer 17c is provided between the source electrode 16aa and the drain electrode 16b, and the oxide semiconductor layer 13a, has a multilayer structure, has been illustrated. In this embodiment, an active matrix substrate 20i in which the interlayer insulating layer 18 has a single-layer structure will be illustrated.

As shown in FIG. 15(b), in the active matrix substrate 20i, the interlayer insulating layer 18 covering the TFT 5h has a single-layer structure. In other respects, the active matrix substrate 20i has substantially the same configuration as that of the active matrix substrate 20h of the eighth embodiment.

Next, an example method for manufacturing the active matrix substrate 20i of this embodiment will be described with reference to FIG. 15.

Next, on the entire substrate on which the source electrode 16aa and the drain electrode 16b have been formed by performing the source/drain forming step of the active matrix substrate manufacturing process of the eighth embodiment, a photosensitive organic insulating film having a thickness of about 1.0-3.0 μm is applied by spin coating or slit coating, and thereafter, exposure and development are performed on the applied film, whereby, as shown in FIG. 15(a), the interlayer insulating layer 18 is formed (interlayer insulating layer forming step).

Moreover, on the entire substrate on which the interlayer insulating layer 18 has been formed, a transparent conductive film such as an ITO film (thickness: about 50-200 nm), etc. is formed by sputtering, and thereafter, photolithography, wet etching, and resist removal and cleaning are performed on the transparent conductive film. As a result, as shown in FIG. 15(b), the pixel electrode 19a is formed (pixel electrode forming step).

Thus, the active matrix substrate 20i can be manufactured.

As described above, according to the active matrix substrate 20i of this embodiment and the method for manufacturing the active matrix substrate 20i, as in the eighth embodiment, the protection insulating layer 17c made of an SOG material is provided on the channel region C of the oxide semiconductor layer 13a. As a result, an increase in the number of manufacturing steps can be reduced, the damage to the oxide semiconductor layer 13a can be reduced, and satisfactory TFT characteristics can be obtained.

Also, according to the active matrix substrate 20i of this embodiment, the interlayer insulating layer 18 is formed of a photosensitive resin film. Therefore, the interlayer insulating layer 18 having a single-layer structure can be formed without using a photoresist. As a result, the manufacturing cost of the active matrix substrate 20i can be reduced.

### Tenth Embodiment of the Invention

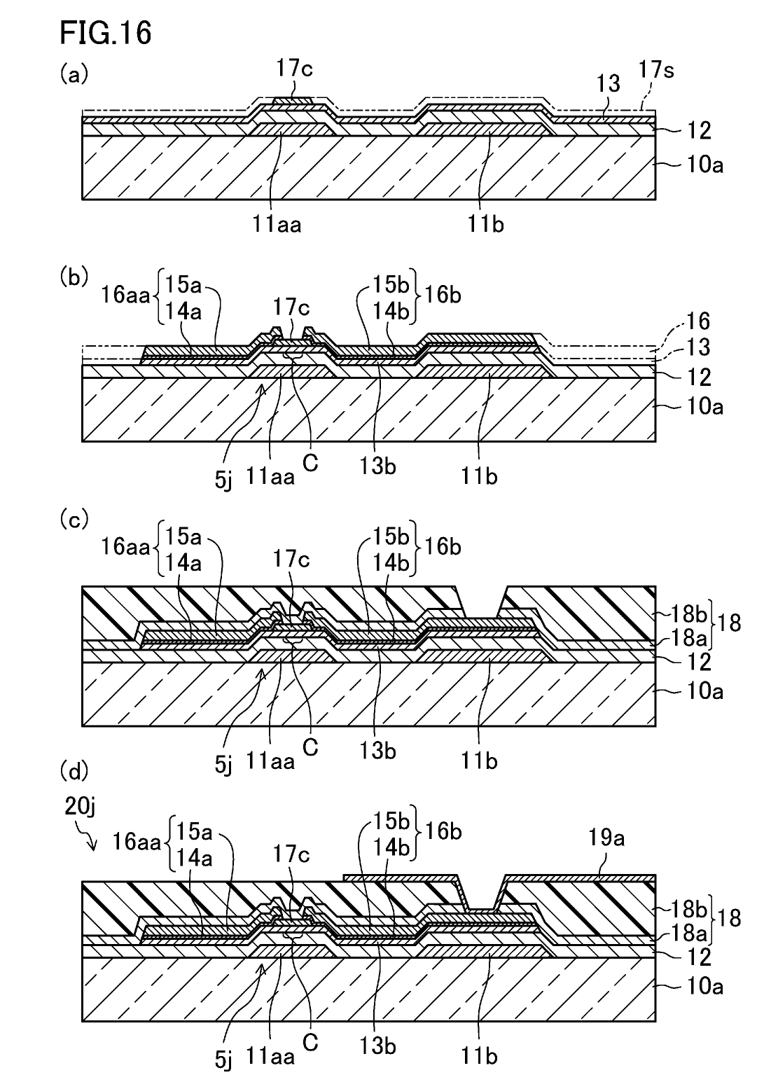

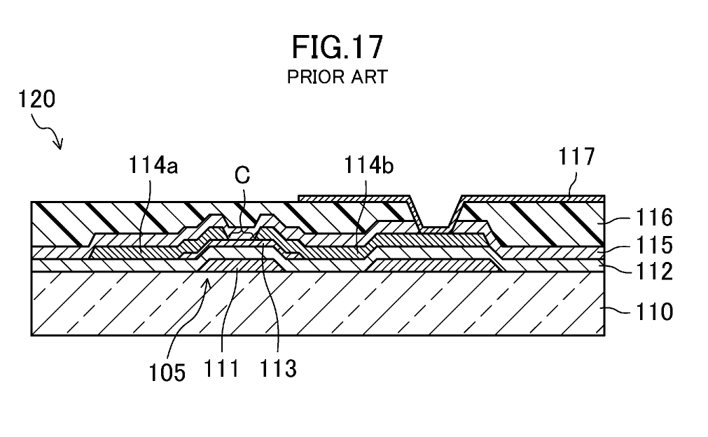

FIG. 16 shows cross-sectional views for describing a process of manufacturing an active matrix substrate 20j of this embodiment.

In the eighth and ninth embodiments, the active matrix substrate which includes the TFT 5h including the relatively small oxide semiconductor layer 13a has been illustrated. In this embodiment, the active matrix substrate 20j which includes a TFT 5j including a relatively large oxide semiconductor layer 13b will be illustrated.

As shown in FIG. 16(d), the active matrix substrate 20j includes the TFT 5ⱼ in which the oxide semiconductor layer 13b is formed not only in an upper layer portion of the gate electrode 11aa, but also in entire lower layer portions of the source electrode 16aa and the drain electrode 16b. In other respects, the active matrix substrate 20j has substantially the same configuration as that of the active matrix substrate 20h of the eighth embodiment.

Next, an example method for manufacturing the active matrix substrate 20j of this embodiment will be described with reference to FIG. 16.

Initially, on the entire substrate on which the gate electrode 11aa and the auxiliary capacitor line 11b, etc., have been formed by performing the gate electrode forming step of the active matrix substrate manufacturing process of the first embodiment, for example, a silicon nitride film (thickness: about 200-500 nm) is formed as the gate insulating layer 12 by CVD. Thereafter, for example, an IGZO oxide semiconductor film 13 (thickness: about 30-300 nm) is continuously formed by CVD. Moreover, a spin-on glass (SOG) material containing, for example, silanol (Si(OH)₄), alkoxysilane, or organic siloxane resin, etc., as a major component, is applied by spin coating or slit coating, and thereafter, is baked at 350° C., to form an SOG film 17s having a thickness of about 500-3000 nm. Thereafter, photolithography, dry etching, and resist removal and cleaning are performed on the SOG film 17s, whereby, as shown in FIG. 16(a), the protection insulating layer 17c is formed (protection insulating layer forming step). While, in this embodiment, the gate insulating layer 12 having a single-layer structure including a silicon nitride film has been illustrated, the gate insulating layer 12 may have a single-layer structure including a silicon oxide film or a multilayer structure including a silicon oxide film (upper layer) and a silicon nitride film (lower layer), for example.

Next, on the entire substrate on which the protection insulating layer 17c has been formed, for example, a titanium film (thickness: about 30-100 nm) and a copper film (thickness: about 100-400 nm), etc., are successively formed by sputtering to form the metal film 16. Thereafter, photolithography and wet etching are performed on the copper film of the metal film 16, and dry etching and resist removal and cleaning are performed on the titanium film of the metal film 16, whereby, as shown in FIG. 16(b), the source electrode 16aa, the drain electrode 16b, and the oxide semiconductor layer 13b are formed (semiconductor layer forming step).

Next, on the entire substrate on which the source electrode 16aa, the drain electrode 16b, and the oxide semiconductor layer 13b have been formed, a CVD film such as a silicon nitride film (thickness: about 100-700 nm), etc. is formed by CVD, and thereafter, a photosensitive organic insulating film having a thickness of about 1.0-3.0 μm is applied by spin coating or slit coating, and thereafter, exposure and development are performed on the applied film, to form the second interlayer insulating layer 18b. Thereafter, dry etching is performed on the CVD film exposed through the second interlayer insulating layer 18b, whereby, as shown in FIG. 16(c), the first interlayer insulating layer 18a is formed (interlayer insulating layer forming step).

Finally, on the entire substrate on which the first and second interlayer insulating layers 18a and 18b have been formed, a transparent conductive film such as an ITO film (thickness: about 50-200 nm), etc. is formed by sputtering, and thereafter, photolithography, wet etching, and resist removal and cleaning are performed on the transparent conductive film. As a result, as shown in FIG. 16(d), the pixel electrode 19a is formed (pixel electrode forming step).

Thus, the active matrix substrate 20j can be manufactured.

As described above, according to the active matrix substrate 20j of this embodiment and the method for manufacturing the active matrix substrate 20j, after the source electrode 16aa and the drain electrode 16b are formed in the semiconductor layer forming step, the oxide semiconductor layer 13b is formed by utilizing the formation of the source electrode 16aa and the drain electrode 16b. Therefore, the active matrix substrate 20j which includes the TFT 5j in which the relatively large oxide semiconductor layer 13b is formed in conjunction with the formation of the source electrode 16aa and the drain electrode 16b, can be manufactured. In the protection insulating layer forming step, an SOG material is applied by spin coating or slit coating to cover the oxide semiconductor film 13 of which the oxide semiconductor layer 13b is to be formed, and baking and patterning are performed on the applied film, to form the protection insulating layer 17c on a region of the oxide semiconductor layer 13b in which the channel region C is to be formed. Therefore, the channel region C of the oxide semiconductor layer 13b is not exposed to plasma, and therefore, the damage to the channel region C of the oxide semiconductor layer 13b can be reduced. Also, when patterning is performed on the metal film 16 by dry etching in order to form the source electrode 16aa and the drain electrode 16b in the semiconductor layer forming step, the protection insulating layer 17c on the oxide semiconductor film 13 functions as an etch stopper for the oxide semiconductor film 13, and therefore, the damage to the channel region C of the oxide semiconductor layer 13b can be reduced. Also, when the protection insulating layer 17c is formed in the protection insulating layer forming step, the applied film of the SOG material is baked. During the baking, H₂O occurs due to dehydration polymerization reaction of the SOG material. Therefore, when the applied film is baked in the protection insulating layer forming step, H₂O occurs, and therefore, the oxide semiconductor film 13 forming the oxide semiconductor layer 13b is annealed in the presence of H₂O. Therefore, even if a region where the channel region C of the oxide semiconductor film 13 is to be formed is damaged, the damage to the region where the channel region C of the oxide semiconductor film 13 is to be formed can be satisfactorily repaired. Thus, by forming the protection insulating layer 17c by applying, baking, and patterning the SOG material, the damage to the channel region C of the oxide semiconductor layer 13b can be reduced and repaired. As a result, an increase in the number of manufacturing steps can be reduced, the damage to the oxide semiconductor layer 13b can be reduced, and satisfactory TFT characteristics can be obtained.

While, in the above embodiments, the multilayer structure of copper (Cu) and titanium (Ti) has been illustrated as an interconnect layer, the metal of the lower layer may be, in addition to titanium, molybdenum (Mo), molybdenum nitride (MoN), titanium nitride (TiN), tungsten (W), niobium (Nb), tantalum (Ta), molybdenum titanium (MoTi), or molybdenum tungsten (MoW), etc. While, in the above embodiments, IGZO (In—Ga—Zn—O) has been illustrated as the oxide semiconductor, the oxide semiconductor may be In—Si—Zn—O, In—Al—Zn—O, Sn—Si—Zn—O, Sn—Al—Zn—O, Sn—Ga—Zn—O, Ga—Si—Zn—O, Ga—Al—Zn—O, In—Cu—Zn—O, Sn—Cu—Zn—O, Zn—O, or In—O, etc.

While, in the above embodiments, the non-photosensitive SOG film has been illustrated, a photosensitive SOG film may be employed.

While, in the above embodiments, the active matrix substrate in which the electrode of the TFT connected to the pixel electrode is a drain electrode has been illustrated, the present invention can be applied to an active matrix substrate in which an electrode of the TFT connected to the pixel electrode is called a source electrode. While, in the above embodiments, the active matrix substrate having the Cs on

Common structure has been illustrated, the present invention can be applied to an active matrix substrate having the Cs on Gate structure.

While, in the above embodiments, the liquid crystal display panel including the active matrix substrate has been illustrated as a display panel, the present invention can be applied to other display panels, such as an organic electroluminescence (EL) display panel, an inorganic EL display panel, an electrophoretic display panel, etc.

### INDUSTRIAL APPLICABILITY

As described above, according to the present invention, an increase in the number of manufacturing steps can be reduced, the damage to the oxide semiconductor layer can be reduced, and satisfactory TFT characteristics can be obtained. Therefore, the present invention is useful for an active matrix substrate for use in a large-size liquid crystal television which can display a high-definition image at a high frame rate, etc.

### DESCRIPTION OF REFERENCE CHARACTERS

C CHANNEL REGION
R PHOTOSENSITIVE RESIN FILM
Raa, Rab, Rba, Rbb RESIST PATTERN
5a, 5b, 5h, 5j TFT
10a INSULATING SUBSTRATE
11 as GATE ELECTRODE
GATE INSULATING LAYER
OXIDE SEMICONDUCTOR FILM
13a, 13b OXIDE SEMICONDUCTOR LAYER
16 METAL FILM
16aa SOURCE ELECTRODE
16b DRAIN ELECTRODE
17, 17c PROTECTION INSULATING LAYER
17s SOG FILM (SPIN-ON GLASS MATERIAL)
18 INTERLAYER INSULATING LAYER
19a PIXEL ELECTRODE
20a, 20b, 20e-20j ACTIVE MATRIX SUBSTRATE

1. An active matrix substrate comprising:
a plurality of pixel electrodes arranged in a matrix; and
a plurality of thin film transistors connected to the respective corresponding pixel electrodes,
wherein
each of the thin film transistors includes a gate electrode provided on an insulating substrate, a gate insulating layer covering the gate electrode, an oxide semiconductor layer provided on the gate insulating layer and having a channel region over the gate electrode, and a source electrode and a drain electrode provided on the oxide semiconductor layer, overlapping the gate electrode and facing each other with the channel region being interposed between the source and drain electrodes, and
a protection insulating layer made of a spin-on glass material is provided on the channel region of the oxide semiconductor layer.

2. The active matrix substrate of claim 1, wherein
the protection insulating layer covers the source and drain electrodes.

3. The active matrix substrate of claim 2, wherein
each of the pixel electrodes is provided on the protection insulating layer.

4. The active matrix substrate of claim 2, wherein
an interlayer insulating layer is provided on the protection insulating layer, and each of the pixel electrodes is provided on the interlayer insulating layer.

5. The active matrix substrate of claim 1, wherein
the protection insulating layer is provided between the source and drain electrodes and the oxide semiconductor layer.

6. The active matrix substrate of claim 5, wherein
an interlayer insulating layer is provided over the source and drain electrodes, covering the protection insulating layer.

7. The active matrix substrate of claim 4, wherein
the interlayer insulating layer is formed of a photosensitive resin film.

8. The active matrix substrate of claim 4, wherein
the interlayer insulating layer is formed of a multilayer film in which a chemically deposited film and a photosensitive resin film are successively stacked.

9. A method for manufacturing an active matrix substrate, wherein
the active matrix substrate includes
a plurality of pixel electrodes arranged in a matrix, and
a plurality of thin film transistors connected to the respective corresponding pixel electrodes,
each of the thin film transistors includes a gate electrode provided on an insulating substrate, a gate insulating layer covering the gate electrode, an oxide semiconductor layer provided on the gate insulating layer and having a channel region over the gate electrode, and a source electrode and a drain electrode provided on the oxide semiconductor layer, overlapping the gate electrode and facing each other with the channel region being interposed between the source and drain electrodes, and
the method comprises:
a gate electrode forming step of forming the gate electrode on the insulating substrate;
a semiconductor layer forming step of forming the gate insulating layer to cover the gate electrode formed in the gate electrode forming step, and thereafter, forming the oxide semiconductor layer on the gate insulating layer;
a source/drain forming step of forming the source and drain electrodes on the oxide semiconductor layer formed in the semiconductor layer forming step; and
a protection insulating layer forming step of applying a spin-on glass material to cover the source and drain electrodes formed in the source/drain forming step, and thereafter, baking the applied spin-on glass material and patterning the baked spin-on glass material, to form a protection insulating layer on the channel region of the oxide semiconductor layer.

10. A method for manufacturing an active matrix substrate, wherein
the active matrix substrate includes
a plurality of pixel electrodes arranged in a matrix, and
a plurality of thin film transistors connected to the respective corresponding pixel electrodes,
each of the thin film transistors includes a gate electrode provided on an insulating substrate, a gate insulating layer covering the gate electrode, an oxide semiconductor layer provided on the gate insulating layer and having a channel region over the gate electrode, and a source electrode and a drain electrode provided on the oxide semiconductor layer, overlapping the gate electrode and facing each other with the channel region being interposed between the source and drain electrodes, and
the method comprises:
a gate electrode forming step of forming the gate electrode on the insulating substrate;
a semiconductor layer forming step of forming the gate insulating layer to cover the gate electrode formed in the gate electrode forming step, and thereafter, successively forming an oxide semiconductor film and a metal film on the gate insulating layer and patterning the metal film to form the source and drain electrodes, and patterning the oxide semiconductor film to form the oxide semiconductor layer; and
a protection insulating layer forming step of applying a spin-on glass material to cover the source and drain electrodes formed in the semiconductor layer forming step, and thereafter, baking the applied spin-on glass material and patterning the baked spin-on glass material, to form a protection insulating layer on the channel region of the oxide semiconductor layer.

11. The method of claim 10, wherein
in the semiconductor layer forming step, a photosensitive resin film is formed on the metal film, and thereafter, half exposure is performed on the photosensitive resin film, to form a resist pattern having a relatively thin portion in which the channel region is to be formed and a relatively thick portion in which the source and drain electrodes are to be formed, and thereafter, the metal film exposed through the resist pattern and the oxide semiconductor film which is located below the metal film are etched to form the oxide semiconductor layer, and thereafter, the metal film exposed by removing a relatively thin portion of the resist pattern by reducing a thickness of the resist pattern is etched to form the source and drain electrodes.

12. The method of claim 10, wherein
in the semiconductor layer forming step, after patterning is performed on the metal film to form the source and drain electrodes, the oxide semiconductor film exposed through the source and drain electrodes is etched to form the oxide semiconductor layer.

13. The method of claim 12, wherein
in the semiconductor layer forming step, a resist pattern is formed on the metal film to cover portions in which the source and drain electrodes are to be formed, and thereafter, the metal film exposed through the resist pattern is etched to form the source and drain electrodes, and reflowing is performed on the resist pattern to cover a portion in which the channel region is to be formed, and thereafter, the oxide semiconductor film is etched to form the oxide semiconductor layer.

14. A method for manufacturing an active matrix substrate, wherein
the active matrix substrate includes
a plurality of pixel electrodes arranged in a matrix, and
a plurality of thin film transistors connected to the respective corresponding pixel electrodes,
each of the thin film transistors includes a gate electrode provided on an insulating substrate, a gate insulating layer covering the gate electrode, an oxide semiconductor layer provided on the gate insulating layer and having a channel region over the gate electrode, and a source electrode and a drain electrode provided on the oxide semiconductor layer, overlapping the gate electrode and facing each other with the channel region being interposed between the source and drain electrodes, and
the method comprises:
a gate electrode forming step of forming the gate electrode on the insulating substrate;
a semiconductor layer forming step of forming the gate insulating layer to cover the gate electrode formed in the gate electrode forming step, and thereafter, forming the oxide semiconductor layer on the gate insulating layer;
a protection insulating layer forming step of applying a spin-on glass material to cover the oxide semiconductor layer formed in the semiconductor layer forming step, and thereafter, baking the applied spin-on glass material and patterning the baked spin-on glass material, to form a protection insulating layer on the channel region of the oxide semiconductor layer; and
a source/drain forming step of forming the source and drain electrodes on the protection insulating layer formed in the protection insulating layer forming step.

15. A method for manufacturing an active matrix substrate, wherein
the active matrix substrate includes
a plurality of pixel electrodes arranged in a matrix, and
a plurality of thin film transistors connected to the respective corresponding pixel electrodes,
each of the thin film transistors includes a gate electrode provided on an insulating substrate, a gate insulating layer covering the gate electrode, an oxide semiconductor layer provided on the gate insulating layer and having a channel region over the gate electrode, and a source electrode and a drain electrode provided on the oxide semiconductor layer, overlapping the gate electrode and facing each other with the channel region being interposed between the source and drain electrodes, and the method comprises:
a gate electrode forming step of forming the gate electrode on the insulating substrate;
a protection insulating layer forming step of forming the gate insulating layer to cover the gate electrode formed in the gate electrode forming step, and thereafter, forming an oxide semiconductor film on the gate insulating layer, and thereafter, applying a spin-on glass material, and thereafter, baking the applied spin-on glass material and patterning the baked spin-on glass material, to form a protection insulating layer on a region in which the channel region of the oxide semiconductor layer is to be formed; and
a semiconductor layer forming step of forming a metal film to cover the protection insulating layer formed in the protection insulating layer forming step, and thereafter, patterning the metal film, to form the source and drain electrodes, and thereafter, etching the oxide semiconductor film exposed through the source and drain electrodes to form the oxide semiconductor layer.
